(19) United States
(12) Patent Application Publication
(10) Pub. No.: US 2024/0118866 A1
(43) Pub. Date: Apr. 11, 2024

(54) SHIFT ARRAY CIRCUIT AND ARITHMETIC CIRCUIT INCLUDING THE SHIFT ARRAY CIRCUIT

(71) Applicant: SK hynix Inc., Icheon-si Gyeonggi-do (KR)

(72) Inventors: Seong Ju LEE, Icheon-si Gyeonggi-do (KR); Choung Ki SONG, Icheon-si Gyeonggi-do (KR)

(73) Assignee: SK hynix Inc., Icheon-si Gyeonggi-do (KR)

(21) Appl. No.: 18/182,219

(22) Filed: Mar. 10, 2023

(30) Foreign Application Priority Data
Oct. 7, 2022 (KR) 10-2022-0129100

(51) Int. Cl. G06F 5/01

(52) U.S. Cl. CPC G06F 5/012

(57) ABSTRACT

A shift array circuit generates output data having the number of bits greater than the number of bits of target data by shifting the target data by a bit corresponding to a value of shift data. The shift array circuit includes a plurality of shift arrays. The plurality of shift arrays is configured to receive bits of the shift data for each bit and each configured to perform a shift operation on input data that is input to each of the plurality of shift arrays by a shift bit corresponding to an input bit, among the bits of the shift data.

### CROSS-REFERENCE TO RELATED APPLICATION

The present application claims priority under 35 U.S.C. § 119(a) to Korean application number 10-2022-0129100, filed in the Korean Intellectual Property Office on Oct. 7, 2022, the entire disclosure of which is incorporated herein by reference.

### BACKGROUND

### 1. Technical Field

The present disclosure relates to a shift array circuit, and more particularly, to an arithmetic circuit including the shift array circuit.

### 2. Related Art

A shift operation for shifting data is required for several application fields including arithmetic operations, variable-length coding, and bit-indexing. Particularly, in a deep learning operation of artificial intelligence, the shift operation is one of operations that are frequently used. Accordingly, an area that is occupied by a shift circuit has a great influence on a total area of an artificial intelligence neural network circuit. The shift circuit may be implemented by using multiplexers. If the shift circuit is constructed so that the multiplexers receive all the bits of input data and bits of the input data are selected based on a value of shift data, a large circuit area and a complicated wiring structure are required due to many input terminals of the multiplexers. Furthermore, in order to provide a selection signal to the multiplexers, a decoder that decodes the shift data is also additionally required.

### SUMMARY

In an embodiment, a shift array circuit may generate output data having the number of bits greater than the number of bits of target data by shifting the target data by a bit corresponding to a value of shift data. The shift array circuit may include a plurality of shift arrays. The plurality of shift arrays may be configured to receive bits of the shift data for each bit and each configured to perform a shift operation on input data that is input to each of the plurality of shift arrays by a shift bit corresponding to an input bit, among the bits of the shift data.

In another embodiment, an arithmetic circuit may include a multiplication circuit configured to output a plurality of multiplication data by performing a multiplication operation on first input data and second input data having a floating-point format, a plurality of shift array circuits configured to output shifted mantissa data by shifting mantissa data of the multiplication data by bits corresponding to a value of shift data with respect to each of the plurality of multiplication data, and an addition circuit configured to add shifted mantissa data from a shift circuit. Each of the plurality of shift array circuits may include a plurality of shift arrays configured to receive bits of the shift data for each bit and each configured to perform a shift operation on input data that is input to each of the plurality of shift arrays by a shift bit corresponding to an input bit among the bits of the shift data.

### BRIEF DESCRIPTION OF THE DRAWINGS

Certain features of the disclosed technology are illustrated by various embodiments with reference to the attached drawings, in which:

FIG. 1 is a block diagram illustrating a shift array circuit according to an example of the present disclosure.

FIG. 2 is a circuit diagram illustrating a first shift array that is included in the shift array circuit of FIG. 1.

FIG. 3 is a circuit diagram illustrating a second shift array that is included in the shift array circuit of FIG. 1.

FIG. 4 is a circuit diagram illustrating a third shift array that is included in the shift array circuit of FIG. 1.

FIG. 5 is a circuit diagram illustrating a fourth shift array that is included in the shift array circuit of FIG. 1.

FIG. 6 is a circuit diagram illustrating a fifth shift array that is included in the shift array circuit of FIG. 1.

FIG. 7 is a diagram illustrated to describe an example of a common rule that is applied to a shift array that constitutes a shift array circuit according to an embodiment of the present disclosure.

FIG. 8 is a diagram illustrated to describe another example of the common rule that is applied to a shift array that constitutes a shift array circuit according to an embodiment of the present disclosure.

FIG. 9 is a diagram illustrated to describe still another example of the common rule that is applied to a shift array that constitutes a shift array circuit according to an embodiment of the present disclosure.

FIG. 10 is a diagram illustrated to describe an example of a multiplication accumulation (MAC) operation that is performed in an arithmetic circuit according to an example of the present disclosure and a floating-point format of weight data.

FIG. 11 is a diagram illustrated to describe a process of matrix multiplication in FIG. 10 being performed in an arithmetic circuit in which a unit operation size is 128 bits.

FIG. 12 is a block diagram illustrating an arithmetic circuit according to an example of the present disclosure.

FIG. 13 is a block diagram illustrating a multiplication circuit that is included in the arithmetic circuit of FIG. 12.

FIG. 14 is a circuit diagram illustrating a first multiplier that is included in the multiplication circuit of FIG. 13.

FIG. 15 is a block diagram illustrating a shift circuit that is included in the arithmetic circuit of FIG. 12.

FIG. 16 is a block diagram illustrating a comparison circuit that is included in the shift circuit of FIG. 15.

FIG. 17 is a block diagram illustrating a first shifter that is included in the shift circuit of FIG. 15.

FIG. 18 is a block diagram illustrating a shift array circuit that is included in the first shifter of FIG. 17.

FIG. 19 is a diagram illustrating a comparison between a shift operation speed of the shifter in FIG. 17 and a shift operation speed of a comparative example of a shift circuit.

FIG. 20 is a block diagram illustrating an addition circuit that is included in the arithmetic circuit of FIG. 12.

FIG. 21 is a block diagram illustrating an accumulator that is included in the arithmetic circuit of FIG. 12.

FIG. 22 is a block diagram illustrating a mantissa processing circuit that is included in the accumulator of FIG. 21.

FIG. 23 is a block diagram illustrating a first shift array circuit that is included in the mantissa processing circuit of FIG. 22.

FIG. 24 is a block diagram illustrating a second shift array circuit that is included in the mantissa processing circuit of FIG. 22.

FIG. 25 is a circuit diagram illustrating a first shift array that is included in the second shift array circuit of FIG. 24.

FIG. 26 is a circuit diagram illustrating a second shift array that is included in the second shift array circuit of FIG. 24.

FIG. 27 is a circuit diagram illustrating a third shift array that is included in the second shift array circuit of FIG. 24.

FIG. 28 is a circuit diagram illustrating a fourth shift array that is included in the second shift array circuit of FIG. 24.

FIG. 29 is a circuit diagram illustrating a fifth shift array that is included in the second shift array circuit of FIG. 24.

### DETAILED DESCRIPTION

In the following description of embodiments, it will be understood that the terms “first” and “second” are intended to identify elements, but not used to define a particular number or sequence of elements. In addition, when an element is referred to as being located “on,” “over,” “above,” “under,” or “beneath” another element, it is intended to mean relative positional relationship, but not used to limit certain cases for which the element directly contacts the other element, or at least one intervening element is present between the two elements. Accordingly, the terms such as “on,” “over,” “above,” “under,” “beneath,” “below,” and the like that are used herein are for the purpose of describing particular embodiments only and are not intended to limit the scope of the present disclosure. Further, when an element is referred to as being “connected” or “coupled” to another element, the element may be electrically or mechanically connected or coupled to the other element directly, or may be electrically or mechanically connected or coupled to the other element indirectly with one or more additional elements between the two elements. Moreover, when a parameter is referred to as being “predetermined,” it may be intended to mean that a value of the parameter is determined in advance of when the parameter is used in a process or an algorithm. The value of the parameter may be set when the process or the algorithm starts or may be set during a period in which the process or the algorithm is executed. A logic “high” level and a logic “low” level may be used to describe logic levels of electric signals. A signal having a logic “high” level may be distinguished from a signal having a logic “low” level. For example, when a signal having a first voltage corresponds to a signal having a logic “high” level, a signal having a second voltage may correspond to a signal having a logic “low” level. In an embodiment, the logic “high” level may be set as a voltage level which is higher than a voltage level of the logic “low” level. Meanwhile, logic levels of signals may be set to be different or opposite according to embodiment. For example, a certain signal having a logic “high” level in one embodiment may be set to have a logic “low” level in another embodiment.

Various embodiments of the present disclosure will be described hereinafter in detail with reference to the accompanying drawings. However, the embodiments described herein are for illustrative purposes only and are not intended to limit the scope of the present disclosure.

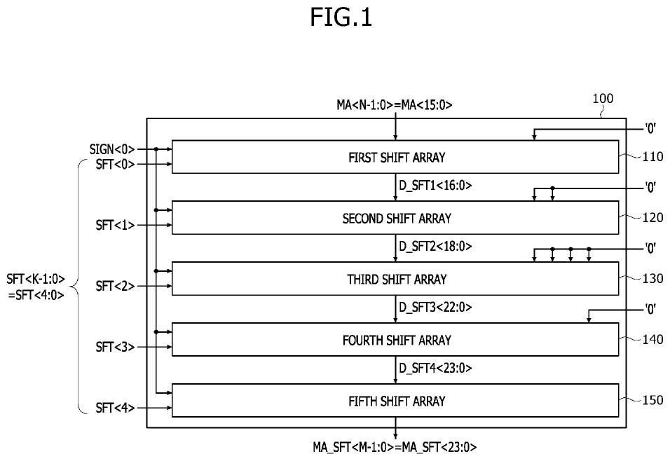

FIG. 1 is a block diagram illustrating a shift array circuit 100 according to an example of the present disclosure. Referring to FIG. 1, the shift array circuit 100 may receive shift data SFT<K−1:0> and mantissa data MA<N−1:0> that are included in floating-point data. In this example, the mantissa data MA<N−1:0> may correspond to target data that is shifted by the shift array circuit 100. The shift data SFT<K−1:0> provides total shift bits to the shift array circuit 100. The “total shift bits” may mean the number of positions at which each of the bits of the mantissa data MA<N−1:0> is shifted by a shift operation of the shift array circuit 100. That is, the shift array circuit 100 may shift the mantissa data MA<N−1:0> by the total shift bits. The shift array circuit 100 may receive the sign data SIGN<0> of the floating-point data and “0”. The sign data SIGN<0> and “0” may constitute an upper bit and lower bit of shift data, respectively, which are generated in a shift process within the shift array circuit 100. The shift array circuit 100 may output shifted mantissa data MA_SFT<M−1:0>.

The mantissa data MA<N−1:0> that are input to the shift array circuit 100 and the shifted mantissa data MA_SFT<M−1:0> that are output by the shift array circuit 100 may be constituted with “N” bits and “M” bits, respectively. In this case, “N” and “M” are natural numbers. In general, “N” may have a value of “_{2T}” (“T” is a natural number equal to or greater than “0”), and “M” may be greater than “N”. The shift data SFT<K−1:0> may be constituted with at least “K” bits. The least number of bits of the shift data SFT<K−1:0> may be determined by output data from the shift array circuit 100, that is, the number “N” of bits of the shifted mantissa data MA_SFT<M−1:0>. The least number of bits “K” of the shift data SFT<K−1:0> may be set as the smallest number, among natural numbers equal to or greater than “log₂M”. In this example, a case in which the mantissa data MA<N−1:0> are 16 bits (i.e., N=16) and the shifted mantissa data MA_SFT<M−1:0> are 24 bits (i.e., M=24) is taken as an example. In this case, the shift data SFT<K−1:0> may be constituted with at least 5 bits.

The shift array circuit 100 may include a plurality of shift arrays that is disposed in a plurality of stages, respectively. The number of shift arrays that are disposed in the shift array circuit 100 may be determined identically with a method of determining the least number of bits of the shift data SFT<K−1:0>. Accordingly, the shift array circuit 100 may include first to fifth shift arrays 110 to 150. The first shift array 110 may be disposed in a first stage. The second shift array 120 may be disposed in a second stage. The third shift array 130 may be disposed in a third stage. The fourth shift array 140 may be disposed in a fourth stage. Furthermore, the fifth shift array 150 may be disposed in a final fifth stage.

The first shift array 110 of the first to fifth shift arrays 110 to 150 may directly receive target data that is input to the shift array circuit 100. The remaining second to fifth shift arrays 120 to 150 may receive, as input data, data that is output by the shift arrays of upper stages. Accordingly, shift operations in respective shift arrays from a first shift operation in the first shift array 110 of the first stage to a fifth shift operation in the fifth shift array 150 of the fifth stage may be sequentially performed within the shift array circuit 100.

The first shift array 110 may receive the first bit SFT<0>, that is, the least significant bit (LSB) of the shift data SFT<4:0>, and mantissa data MA<15:0>. The first shift array 110 may perform or might not perform a shift operation based on a value of the first bit SFT<0> of the shift data SFT<4:0>. In an example, when the first bit SFT<0> of the shift data SFT<4:0> is “0”, the first shift array 110 might not shift the mantissa data MA<15:0>. In contrast, when the first bit SFT<0> of the shift data SFT<4:0> is “1”, the first shift array 110 may shift the mantissa data MA<15:0>. The first shift array 110 may output output data as first shifted data D_SFT1<16:0>.

The second shift array 120 may receive the second bit SFT<1> of the shift data SFT<4:0> and the first shifted data D_SFT1<16:0> that are output by the first shift array 110. The second shift array 120 may perform or might not perform a shift operation based on a value of the second bit SFT<1> of the shift data SFT<4:0>. In an example, when the second bit SFT<1> of the shift data SFT<4:0> is “0”, the second shift array 120 might not shift the first shifted data D_SFT1<16:0>. In contrast, when the second bit SFT<1> of the shift data SFT<4:0> is “1”, the second shift array 120 may shift the first shifted data D_SFT1<16:0>. The second shift array 120 may output output data as second shifted data D_SFT2<18:0>.

The third shift array 130 may receive the third bit SFT<2> of the shift data SFT<4:0> and the second shifted data D_SFT2<18:0> that are output by the second shift array 120. The third shift array 130 may perform or might not perform a shift operation based on a value of the third bit SFT<2> of the shift data SFT<4:0>. In an example, when the third bit SFT<2> of the shift data SFT<4:0> is “0”, the third shift array 130 might not shift the second shifted data D_SFT2<18:0>. In contrast, when the third bit SFT<2> of the shift data SFT<4:0> is “1”, the third shift array 130 may shift the second shifted data D_SFT2<18:0>. The third shift array 130 may output output data as third shifted data D_SFT3<22:0>.

The fourth shift array 140 may receive the fourth bit SFT<3> of the shift data SFT<4:0> and the third shifted data D_SFT3<22:0> that are output by the third shift array 130. The fourth shift array 140 may perform or might not perform a shift operation based on a value of the fourth bit SFT<3> of the shift data SFT<4:0>. In an example, when the fourth bit SFT<3> of the shift data SFT<4:0> is “0”, the fourth shift array 140 might not shift the third shifted data D_SFT3<22:0>. In contrast, when the fourth bit SFT<3> of the shift data SFT<4:0> is “1”, the fourth shift array 140 may shift the third shifted data D_SFT3<22:0>. The fourth shift array 140 may output output data as fourth shifted data D_SFT4<23:0>.

The fifth shift array 150 may receive the fifth bit SFT<4> of the shift data SFT<4:0> and the fourth shifted data D_SFT4<23:0> that are output by the fourth shift array 140. The fifth shift array 150 may perform or might not perform a shift operation based on a value of the fifth bit SFT<4> of the shift data SFT<4:0>. In an example, when the fifth bit SFT<4> of the shift data SFT<4:0> is “0”, the fifth shift array 150 might not shift the fourth shifted data D_SFT4<23:0>. In contrast, when the fifth bit SFT<4> of the shift data SFT<4:0> is “1”, the fifth shift array 150 may shift the fourth shifted data D_SFT4<23:0>. The fifth shift array 150 may output output data as shifted mantissa data MA_SFT<23:0>, that is, final output data of the shift array circuit 100.

First to fifth bits of the shift data SFT<4:0> that are provided to the shift array circuit 100 may be transmitted to the first to fifth shift arrays 110 to 150, respectively. The first to fifth bits of the shift data SFT<4:0> may provide the first to fifth shift bits to the first to fifth shift arrays 110 to 150, respectively. The first shift bit in the first shift array 110 may become 1 bit corresponding to a binary weight (i.e., “20=1”) of the first bit SFT<0> of the shift data SFT<4:0>. Accordingly, when the first bit SFT<0> of the shift data SFT<4:0> is “1”, the first shift array 110 may shift the mantissa data MA<15:0> by 1 bit. The second shift bit in the second shift array 120 may become 2 bits corresponding to a binary weight (i.e., “2¹=2”) of the second bit SFT<1> of the shift data SFT<4:0>. Accordingly, when the second bit SFT<1> of the shift data SFT<4:0> is “1”, the second shift array 120 may shift the first shifted data D_SFT1<16:0> by 2 bits. The third shift bit in the third shift array 130 may become 4 bits corresponding to a binary weight (i.e., “2²=4”) of the third bit SFT<2> of the shift data SFT<4:0>. Accordingly, when the third bit SFT<2> of the shift data SFT<4:0> is “1”, the third shift array 130 may shift the second shifted data D_SFT2<18:0> by 4 bits. The fourth shift bit in the fourth shift array 140 may become 8 bits corresponding to a binary weight (i.e., “23=8”) of the fourth bit SFT<3> of the shift data SFT<4:0>. Accordingly, when the fourth bit SFT<3> of the shift data SFT<4:0> is “1”, the fourth shift array 140 may shift the third shifted data D_SFT3<22:0> by 8 bits. The fifth shift bit in the fifth shift array 150 may become 16 bits corresponding to a binary weight (i.e., “24=16”) of the fifth bit SFT<4> of the shift data SFT<4:0>. Accordingly, when the fifth bit SFT<4> of the shift data SFT<4:0> is “1”, the fifth shift array 150 may shift the fourth shifted data D_SFT4<23:0> by 16 bits.

The number of bits of the first to fourth shifted data D_SFT1-D_SFT4 that are output by the first to fourth shift arrays 110 to 140 may be determined as a sum value obtained by adding the number of bits of input data and a shift bit or may be determined as the same number of bits as the number of bits of the shifted mantissa data MA_SFT<23:0>, based on a result of a comparison between the numbers of bits of the shifted mantissa data MA_SFT<23:0> that are finally output by the shift array circuit 100. Specifically, if the sum value is smaller than the number of bits of the shifted mantissa data MA_SFT<23:0>, shifted data that is output by a shift array may have the number of bits corresponding to the sum value. In contrast, if the sum value is equal to or greater than the number of bits of the shifted mantissa data MA_SFT<23:0>, shifted data that is output by a shift array may have the same number of bits as the number of bits of the shifted mantissa data MA_SFT<23:0>, that is, output data of the shift array circuit 100.

In the case of the first shift array 110, a sum value “17” that is obtained by adding the number “16” of bits of the mantissa data MA<15:0>, that is, target data, and “1”, that is, the first shift bit, may be smaller than “24”, that is, the number of bits of the shifted mantissa data MA_SFT<23:0>. Accordingly, the first shift array 110 may output the first shifted data D_SFT1<16:0> having 17 bits. Even in the case of the second shift array 120, a sum value “19” that is obtained by adding the number “17” of bits of the first shifted data D_SFT1<16:0>, that is, input data, and “2”, that is, the second shift bit, may be smaller than “24”, that is, the number of bits of the shifted mantissa data MA_SFT<23:0>. Accordingly, the second shift array 120 may output the second shifted data D_SFT2<18:0> having 19 bits. Even in the case of the third shift array 130, a sum value “23” that is obtained by adding the number “19” of bits of the second shifted data D_SFT2<18:0>, that is, input data, and “4”, that is, the third shift bit, may be smaller than “24”, that is, the number of bits of the shifted mantissa data MA_SFT<23:0>. Accordingly, the third shift array 130 may output the third shifted data D_SFT3<22:0> having 23 bits.

In contrast, in the case of the fourth shift array 140, a sum value “32” that is obtained by adding the number “23” of bits of the third shifted data D_SFT3<22:0>, that is, input data, and “8”, that is, the fourth shift bit, may be greater than “24”, that is, the number of bits of the shifted mantissa data MA_SFT<23:0>. Accordingly, the fourth shift array 140 may output the fourth shifted data D_SFT4<23:0> having the same number of bits as the number of bits of the shifted mantissa data MA_SFT<23:0>, 24 bits. The fifth shift array 150 may output the shifted mantissa data MA_SFT<23:0> having 24 bits, that is final output data of the shift array circuit 100.

The first to fifth shift arrays 110 to 150 may receive the sign data of 1 bit SIGN<0> of floating-point data in common. The sign data of 1 bit SIGN<0> of the floating-point data may have a value of “0” when the floating-point data has a positive number, and may have a value of “1” when the floating-point data has a negative number. In the case of a shift array that performs a shift operation, among the first to fifth shift arrays 110 to 150, the sign data SIGN<0> may constitute upper bits of bits of shifted data that is output by the shift array. In this case, the number of upper bits constituted with the sign data SIGN<0> is the same as shift bits in the shift array. Specifically, when the first shift array 110 performs a first shift operation, the sign data SIGN<0> may constitute the most significant bit (MSB) D_SFT1<16> of the first shifted data D_SFT1<16:0> that are output by the first shift array 110. When the second shift array 120 performs a second shift operation, the sign data SIGN<0> may constitute upper 2 bits D_SFT2<18:17> of the second shifted data D_SFT2<18:0> that are output by the second shift array 120. When the third shift array 130 performs a third shift operation, the sign data SIGN<0> may constitute upper 4 bits D_SFT3<22:19> of the third shifted data D_SFT3<22:0> that are output by the third shift array 130. When the fourth shift array 140 performs a fourth shift operation, the sign data SIGN<0> may constitute upper 8 bits S_SFT4<23:16> of the fourth shifted data S_SFT4<23:0> that are output by the fourth shift array 140. When the fifth shift array 150 performs a fifth shift operation, the sign data SIGN<0> may constitute upper 16 bits MA_SFT<23:8> of the shifted mantissa data MA_SFT<23:0> that are output by the fifth shift array 150. In the case of a shift array that does not perform a shift operation, among the first to fifth shift arrays 110 to 150, the sign data SIGN<0> might not be incorporated into shift data that is output by the shift array.

The first to fourth shift arrays 110 to 140 except the last fifth shift array 150, among the first to fifth shift arrays 110 to 150, may receive at least one “0”. The number of “0s” that is input to each of the first to fourth shift arrays 110 to 140 may be determined based on the number of bits of input data that are input to each of the first to fourth shift arrays 110 to 140, a shift bit, and the number of bits of the shifted mantissa data MA_SFT<23:0> that are output by the shift array circuit 100. When a sum value that is obtained by adding the number of bits of input data that is input to a shift array and a shift bit is smaller than the shifted mantissa data MA_SFT<23:0>, the same number of “0s” as the shift bit may be input to the shift array. In contrast, when a sum value that is obtained by adding the number of bits of input data that is input to a shift array and a shift bit is equal to or greater than the shifted mantissa data MA_SFT<23:0>, the same number of “0” as a value that is obtained by subtracting the number of bits of input data from the number of bits of the shifted mantissa data MA_SFT<23:0> may be input to the shift array.

Specifically, in the case of the first shift array 110, the sum value “17” that is obtained by adding the number of bits of the mantissa data MA<15:0>, that is, input data, and “1”, that is, the first shift bit, may be smaller than “24”, that is, the number of bits of the shifted mantissa data MA_SFT<23:0>. Accordingly, the first shift array 110 may receive one “0” corresponding to the first shift bit. The same condition as that of the first shift array 110 may be also applied to the second shift array 120 and the third shift array 130. Accordingly, the second shift array 120 and the third shift array 130 may receive two “0s” and four “0s”, respectively. In contrast, in the case of the fourth shift array 140, the sum value “32” that is obtained by adding the number of bits of the third shifted data D_SFT3<22:0>, that is, input data, and “8”, that is, the fourth shift bit, may be greater than “24”, that is, the number of bits of the shifted mantissa data MA_SFT<23:0>. Accordingly, the fourth shift array 140 may receive one “0” corresponding to a value that is obtained by subtracting the number “23” of bits of the third shifted data D_SFT3<22:0>, that is, input data, from the number “24” of bits of the shifted mantissa data MA_SFT<23:0>. The same condition as that of the fourth shift array 140 may be applied to the fifth shift array 150. Accordingly, the fifth shift array 150 might not receive “0”.

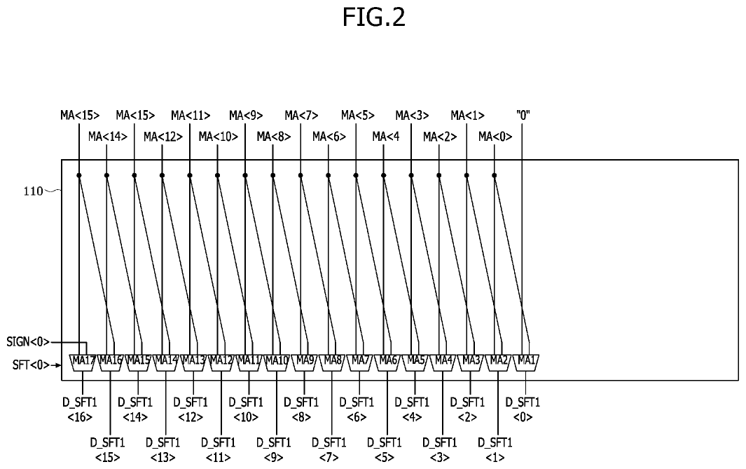

FIG. 2 is a circuit diagram illustrating a construction of the first shift array 110 of the shift array circuit 100 in FIG. 1. Referring to FIG. 2, the first shift array 110 that is disposed in the highest stage of the shift array circuit 100 may include a plurality of multiplexers MA1 to MA17. The number of multiplexers MA1 to MA17 that constitute the first shift array 110 may be the same as the number (i.e., “17”) of bits of the first shifted data D_SFT1<16:0> that are output by the first shift array 110. Hereinafter, the first to seventeenth multiplexers MA1 to MA17 that constitute the first shift array 110 may be denoted as a first group of the first to seventeenth multiplexers MA1 to MA17, for convenience sake. Each of the first to seventeenth multiplexers MA1 to MA17 of the first group may be constituted with a 2:1 multiplexer. Accordingly, each of the first to seventeenth multiplexers MA1 to MA17 of the first group may have a first input terminal, a second input terminal, a selection terminal, and an output terminal. Each of the first to seventeenth multiplexers MA1 to MA17 of the first group may output selection data that is transmitted to the selection terminal, among data that is input to the first input terminal and data that is input to the second input terminal, that is, data that is selected based on a value of the first bit SFT<0> of the shift data SFT<4:0>, through the output terminal.

The first to seventeenth multiplexers MA1 to MA17 of the first group may output bits of the first shifted data D_SFT1<16:0> that are output by the first shift array 110, respectively. Among the first to seventeenth multiplexers MA1 to MA17 of the first group, the first multiplexer MA1 may output the first bit D_SFT1<0>, that is, the least significant bit (LSB) of the first shifted data D_SFT1<16:0> that are output by the first shift array 110. The second multiplexer MA2 may output the second bit D_SFT1<1> of the first shifted data D_SFT1<16:0>. The third multiplexer MA3 may output the third bit D_SFT1<2> of the first shifted data D_SFT1<16:0>. In the same way, the fourth to seventeenth multiplexers MA4 to MA17 may also output the fourth bit to seventeenth bit (i.e., the MSB) D_SFT1<16:0> of the first shifted data D_SFT1<16:0>, respectively.

Among the first to seventeenth multiplexers MA1 to MA17 of the first group, the first multiplexer MA1 may receive “0” through the first input terminal. The second multiplexer MA2 may receive the first bit MA<0> of the mantissa data MA<15:0>, that is, input data, through the first input terminal. The third multiplexer MA3 may receive the second bit MA<1> of the mantissa data MA<15:0> through the first input terminal. In the same way, the fourth to seventeenth multiplexers MA2 to MA16 may receive the third bit MA<2> to sixteenth bit MA<15> of the mantissa data MA<15:0>, respectively, through the first input terminal. That is, the second to seventeenth multiplexers MA2 to MA17 except the first multiplexer MA1, among the first to seventeenth multiplexers MA1 to MA17 of the first group, may receive the mantissa data MA<15:0> through the first input terminal.

Among the first to seventeenth multiplexers MA1 to MA17 of the first group, the first multiplexer MA1 may receive the first bit MA<0> of the mantissa data MA<15:0> through the second input terminal. The second multiplexer MA2 may receive the second bit MA<1> of the mantissa data MA<15:0> through the second input terminal. The third multiplexer MA3 may receive the third bit MA<2> of the mantissa data MA<15:0> through the second input terminal. In the same way, the fourth to sixteenth multiplexers MA4 to MA16 may receive the fourth bit MA<3> to sixteenth bit MA<15> of the mantissa data MA<15:0> through the second input terminals, respectively. The seventeenth multiplexer MA<17 may receive the sign data SIGN<0> through the second input terminal. That is, the first to sixteenth multiplexers MA1 to MA16 except the seventeenth multiplexer MA<17, among the first to seventeenth multiplexers MA1 to MA17 of the first group, may receive the mantissa data MA<15:0> through the second input terminals, respectively.

The first to seventeenth multiplexers MA1 to MA17 of the first group may receive the first bit SFT<0> of the shift data SFT<4:0> in common through the respective selection terminals. When the first bit SFT<0> of the shift data SFT<4:0> is “0”, all of the first to seventeenth multiplexers MA1 to MA17 of the first group may output data that are input through the first input terminals. In this case, the first shift array 110 may additionally output only a lower 1 bit having a value of “0”, and may output the mantissa data MA<15:0>, that is, the input data, without any change without shifting the mantissa data MA<15:0>. Specifically, the mantissa data MA<15:0> that are input through the first input terminals of the second to seventeenth multiplexers MA2 to MA17 may be output as the second to seventeenth bits D_SFT1<16:1> of the first shifted data D_SFT1<16:0> through the output terminals of the second to seventeenth multiplexers MA2 to MA17. Furthermore, “0” that is input to the first input terminal of the first multiplexer MA1 may be output as the first bit of the first shifted data D_SFT1<16:0>, that is, the least significant bit D_SFT1<0>, through the output terminal of the first multiplexer MA1.

When the first bit SFT<0> of the shift data SFT<4:0> is “1”, all of the first to seventeenth multiplexers MA1 to MA17 of the first group may output data that are input through the second input terminal. In this case, the first shift array 110 may output the mantissa data MA<15:0>, that is, input data, by shifting the mantissa data MA<15:0> by 1 bit corresponding to a first shift bit. Specifically, the mantissa data MA<15:0> that are input through the second input terminals of the first to sixteenth multiplexers MA1 to MA16 may be output as the first bit S_SFT1<0> to sixteenth bit D_SFT1<15> of the first shifted data D_SFT1<16:0> through the output terminals of the first to sixteenth multiplexers MA1 to MA16. Furthermore, the sign data SIGN<0> that is input to the second input terminal of the seventeenth multiplexer MA<17 may be output as the seventeenth bit of the first shifted data D_SFT1<16:0>, that is, the most significant bit D_SFT1<16>, through the output terminal of the seventeenth multiplexer MA<17.

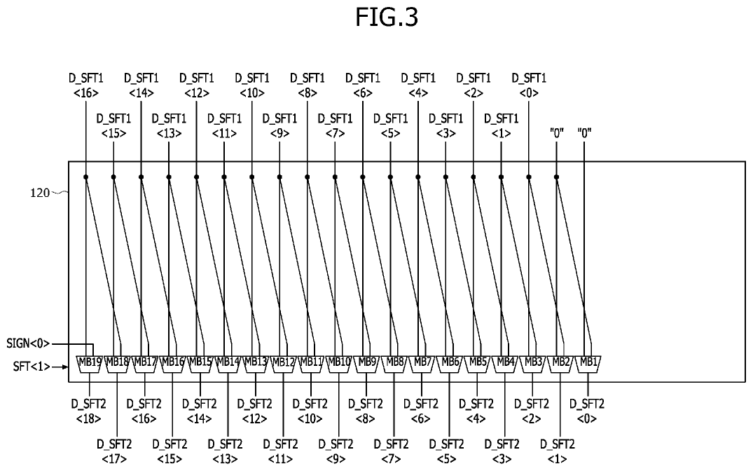

FIG. 3 is a circuit diagram illustrating a construction of the second shift array 120 of the shift array circuit 100 in FIG. 1. Referring to FIG. 3, the second shift array 120 may be disposed in the second stage of the shift array circuit 100, that is, between the first shift array 110, and the third shift array 130. The second shift array 120 may include a plurality of multiplexers MB1 to MB19. The number of multiplexers MB1 to MB19 that constitutes the second shift array 120 may be the same as the number of bits of the second shifted data D_SFT2<18:0> that are output by the second shift array 120. Hereinafter, the first to nineteenth multiplexers MB1 to MB19 that constitute the second shift array 120 may be denoted as a second group of the first to nineteenth multiplexers MB1 to MB19. Each of the first to nineteenth multiplexers MB1 to MB19 of the second group may be constituted with a 2:1 multiplexer. Accordingly, each of the first to nineteenth multiplexers MB1 to MB19 of the second group may have a first input terminal, a second input terminal, a selection terminal, and an output terminal. Each of the first to nineteenth multiplexers MB1 to MB19 of the second group may output selection data that is transmitted to the selection terminal, among data that is input to the first input terminal and data that is input to the second input terminal, that is, data that is selected based on a value of the second bit SFT<1> of the shift data SFT<4:0>, through the output terminal.

The first to nineteenth multiplexers MB1 to MB19 of the second group may output the second shifted data D_SFT2<18:0> that are output by the second shift array 120. Among the first to nineteenth multiplexers MB1 to MB19 of the second group, the first multiplexer MB1 may output the first bit D_SFT2<0>, that is, the least significant bit (LSB) of the second shifted data D_SFT2<18:0> that are output by the second shift array 120. The second multiplexer MB2 may output the second bit D_SFT2<1> of the second shifted data D_SFT2<18:0>. The third multiplexer MB3 may output the third bit D_SFT2<2> of the second shifted data D_SFT2<18:0>. In the same way, the fourth to nineteenth multiplexers MB4 to MB19 may also output the fourth bit to nineteenth bit (i.e., the MSB) D_SFT2<18:3> of the second shifted data D_SFT2<18:0>, respectively.

Among the first to nineteenth multiplexers MB1 to MB19 of the second group, the first multiplexer MB1 and the second multiplexer MB2 may receive “0” through the first input terminals. The third multiplexer MB3 may receive the first bit D_SFT1<0> of the first shifted data D_SFT1<16:0> through the first input terminal. The fourth multiplexer MB4 may receive the second bit D_SFT1<1> of the first shifted data D_SFT1<16:0> through the first input terminal. In the same way, the fifth to nineteenth multiplexers MB5 to MB19 may receive the third bit D_SFT1<2> to seventeenth bit D_SFT1<16> of the first shifted data D_SFT1<16:0> through the first input terminals. That is, the third to nineteenth multiplexers MB3 to MB19 except the first and second multiplexers MB1 and MB2, among the first to nineteenth multiplexers MB1 to MB19 of the second group, may receive bits of the first shifted data D_SFT1<16:0> through the first input terminals, respectively.

Among the first to nineteenth multiplexers MB1 to MB19 of the second group, the first multiplexer MB1 may receive the first bit D_SFT1<0> of the first shifted data D_SFT1<16:0> through the second input terminal. The second multiplexer MB2 may receive the second bit D_SFT1<1> of the first shifted data D_SFT1<16:0> through the second input terminal. The third multiplexer MB3 may receive the third bit D_SFT1<2> of the first shifted data D_SFT1<16:0> through the second input terminal. In the same way, the fourth to seventeenth multiplexers MB4 to MB17 may receive the fourth bit D_SFT1<3> to seventeenth bit D_SFT1<16> of the first shifted data D_SFT1<16:0> through the second input terminals, respectively. The eighteenth multiplexer MB18 and the nineteenth multiplexer MB19 may receive the sign data SIGN<0> through the respective second input terminals. That is, the first to seventeenth multiplexers MB1 to MB17 except the eighteenth and nineteenth multiplexers MB18 and MB19, among the first to nineteenth multiplexers MB1 to MB19 of the second group, may receive bits of the first shifted data D_SFT1<16:0> through the second input terminals, respectively.

The first to nineteenth multiplexers MB1 to MB19 of the second group may receive the second bit SFT<1> of the shift data SFT<4:0> in common through the selection terminals. When the second bit SFT<1> of the shift data SFT<4:0> is “0”, all of the first to nineteenth multiplexers MB1 to MB19 of the second group may output data that are input through the first input terminals. In this case, the second shift array 120 may additionally output only lower 2 bits having a value of “0”, and may output the first shifted data D_SFT1<16:0>, that is, input data, without any change without shifting the first shifted data D_SFT1<16:0>. Specifically, the first shifted data D_SFT1<16:0> that are input through the first input terminals of the third to nineteenth multiplexers MB3 to MB19 of the second group may be output as the third bit D_SFT2<2> to nineteenth bit D_SFT2<18> of the second shifted data D_SFT2<18:0> through the output terminals the third to nineteenth multiplexers MB3 to MB19. Furthermore, “0” that is input to the first input terminals of the first and second multiplexers MB1 and MB2 may be output as the first bit D_SFT2<0> and second bit D_SFT2<1> of the second shifted data D_SFT2<18:0> through the output terminals of the first and second multiplexers MB1 and MB2.

When the second bit SFT<1> of the shift data SFT<4:0> is “1”, all of the first to nineteenth multiplexers MB1 to MB19 of the second group may output data that are input through the second input terminals. In this case, the second shift array 120 may output the first shifted data D_SFT1<16:0>, that is, input data, by shifting the first shifted data D_SFT1<16:0> by 2 bits corresponding to a second shift bit. Specifically, the first shifted data D_SFT1<16:0> that are input through the second input terminals of the first to seventeenth multiplexers MB1 to MB17 may be output as the first bit D_SFT2<0> to seventeenth bit D_SFT2<16> of the second shifted data D_SFT2<18:0> through the output terminals of the first to seventeenth multiplexers MB1 to MB17. Furthermore, the sign data SIGN<0> that is input to the second input terminals of the eighteenth and nineteenth multiplexers MB18 and MB19 may be output as the eighteenth bit D_SFT2<17> and nineteenth bit D_SFT2<18> of the second shifted data D_SFT2<18:0> through the output terminals of the eighteenth and nineteenth multiplexers MB18 and MB19.

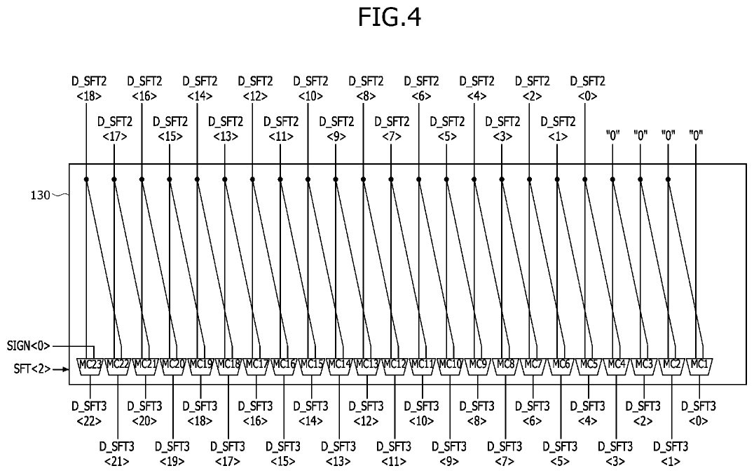

FIG. 4 is a circuit diagram illustrating a construction of the third shift array 130 of the shift array circuit 100 in FIG. 1. Referring to FIG. 4, the third shift array 130 may be disposed in the third stage of the shift array circuit 100, that is, between the second shift array 120 and the fourth shift array 140. The third shift array 130 may include a plurality of multiplexers MC1 to MC23. The number of multiplexers MC1 to MC23 that constitutes the third shift array 130 may be the same as the number of bits of the third shifted data D_SFT3<22:0> that are output by the third shift array 130. Hereinafter, the first to twenty-third multiplexers MC1 to MC23 that constitute the third shift array 130 may be denoted as a third group of the first to twenty-third multiplexers MC1 to MC23. Each of the first to twenty-third multiplexers MC1 to MC23 of the third group may be constituted with a 2:1 multiplexer. Accordingly, each of the first to twenty-third multiplexers MC1 to MC23 of the third group may have a first input terminal, a second input terminal, a selection terminal, and an output terminal. Each of the first to twenty-third multiplexers MC1 to MC23 of the third group may output selection data that is transmitted to the selection terminal, among data that is input to the first input terminal and data that is input to the second input terminal, that is, data that is selected based on a value of the third bit SFT<2> of the shift data SFT<4:0>, through the output terminal.

The first to twenty-third multiplexers MAC1 to MC23 of the third group may output respective bits of the third shifted data D_SFT3<22:0> that are output by the third shift array 130. Among the first to twenty-third multiplexers MC1 to MC23 of the third group, the first multiplexer MC1 may output the first bit D_SFT3<0> of the third shifted data D_SFT3<22:0> that are output by the third shift array 130. The second multiplexer MC2 may output the second bit D_SFT3<1> of the third shifted data D_SFT3<22:0>. The third multiplexer MC3 may output the third bit D_SFT3<2> of the third shifted data D_SFT3<22:0>. In the same way, the fourth to twenty-third multiplexers MC4 to MC23 may also output the fourth bit D_SFT3<3> to twenty-third bit D_SFT3<22> of the third shifted data D_SFT3<22:0>, respectively.

The first multiplexer MC1, the second multiplexer MC2, the third multiplexer MC3, and the fourth multiplexer MC4, among the first to twenty-third multiplexers MC1 to MC23 of the third group, may receive “0” through the first input terminals. The fifth multiplexer MC5 may receive the first bit D_SFT2<0> of the second shifted data D_SFT2<18:0> through the first input terminal. The sixth multiplexer MC6 may receive the second bit D_SFT2<1> of the second shifted data D_SFT2<18:0> through the first input terminal. In the same way, the seventh to twenty-third multiplexers MC7 to MC23 may receive the third bit D_SFT2<2> to nineteenth bit D_SFT2<18> of the second shifted data D_SFT2<18:0> through the first input terminals. That is, the sixth to twenty-third multiplexers MC6 to MC23 except the first to fifth multiplexers MC1-MC5, among the first to twenty-third multiplexers MC1 to MC23 of the third group, may receive bits the second shifted data D_SFT2<18:0> through the first input terminals, respectively.

Among the first to twenty-third multiplexers MC1 to MC23 of the third group, the first multiplexer MC1 may receive the first bit D_SFT2<0> of the second shifted data D_SFT2<18:0> through the second input terminal. The second multiplexer MC2 may receive the second bit D_SFT2<1> of the second shifted data D_SFT2<18:0> through the second input terminal. The third multiplexer MC3 may receive the third bit D_SFT2<2> of the second shifted data D_SFT2<18:0> through the second input terminal. In the same way, the fourth to nineteenth multiplexers MC4 to MC19 may receive the fourth bit D_SFT2<3> to nineteenth bit D_SFT2<18> of the second shifted data D_SFT2<18:0> through the second input terminals, respectively. The twentieth multiplexer MC20, the twenty-first multiplexer MC21, the twenty-second multiplexer MC22, and the twenty-third multiplexer MC23 may receive the sign data SIGN<0> through the respective second input terminals. That is, the first to nineteenth multiplexers MC1 to MC19 except the twentieth to twenty-third multiplexers MC20 to MC23, among the first to twenty-third multiplexers MC1 to MC23 of the third group, may receive bits of the second shifted data D_SFT2<18:0> through the second input terminals, respectively.

The first to twenty-third multiplexers MC1 to MC23 of the third group may receive the third bit SFT<2> of the shift data SFT<4:0> in common through the selection terminals. When the third bit SFT<2> of the shift data SFT<4:0> is “0”, all of the first to twenty-third multiplexers MC1 to MC23 of the third group may output data that are input through the first input terminals. In this case, the third shift array 130 may additionally output only lower 4 bits having a value of “0”, and may output the second shifted data D_SFT2<18:0>, that is, input data, without any change without shifting the second shifted data D_SFT2<18:0>. Specifically, the second shifted data D_SFT2<18:0> that are input through the first input terminals of the fifth to twenty-third multiplexers MC5 to MC23 of the third group may be output as the fifth bit D_SFT3<4> to twenty-third bit D_SFT3<22> of the third shifted data D_SFT3<22:0> through the output terminals of the fifth to twenty-third multiplexers MC5 to MC23. Furthermore, “0” that is input to the first input terminals of the first to fourth multiplexers MC1 to MC4 may be output as the first bit D_SFT3<0> to fourth bit D_SFT3<3> of the third shifted data D_SFT3<22:0> through the output terminals of the first and fourth multiplexers MC1 to MC4.

When the third bit SFT<2> of the shift data SFT<4:0> is “1”, all of the first to twenty-third multiplexers MC1 to MC23 of the third group may output data that are input through the second input terminals. In this case, the third shift array 130 may output the second shifted data D_SFT2<18:0>, that is, input data, by shifting the second shifted data D_SFT2<18:0> by 4 bits corresponding to a third shift bit. Specifically, the second shifted data D_SFT2<18:0> that are input through the second input terminals of the first to nineteenth multiplexers MC1 to MC19 may be output as the first bit D_SFT3<0> to nineteenth bit D_SFT3<18> of the third shifted data D_SFT3<22:0> through the output terminals of the first to nineteenth multiplexers MC1 to MC19. Furthermore, the sign data SIGN<0> that is input to the second input terminals of the twentieth to twenty-third multiplexers MC20 to MC23 may be output as the twentieth bit D_SFT3<19> to twenty-third bit D_SFT3<22> of the third shifted data D_SFT3<22:0> through the output terminals of the twentieth to twenty-third multiplexers MC20 to MC23.

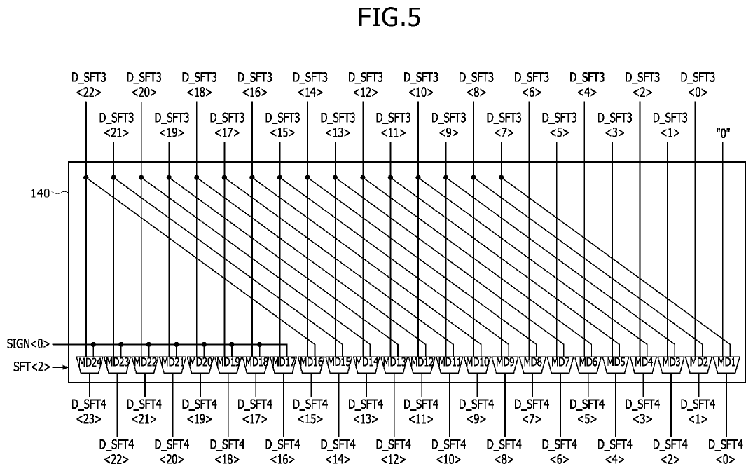

FIG. 5 is a circuit diagram illustrating a construction of the fourth shift array 140 of the shift array circuit 100 in FIG. 1. Referring to FIG. 5, the fourth shift array 140 may be disposed in the fourth stage of the shift array circuit 100, that is, between the third shift array 130 and the fifth shift array 150. The fourth shift array 140 may include a plurality of multiplexers MD1 to MD24. The number of multiplexers MD1 to MD24 that constitute the fourth shift array 140 may be the same as the number of bits of the fourth shifted data D_SFT4<23:0> that are output by the fourth shift array 140. Hereinafter, the first to twenty-fourth multiplexers MD1 to MD24 that constitute the fourth shift array 140 may be denoted as a fourth group of the first to twenty-fourth multiplexers MD1 to MD24. Each of the first to twenty-fourth multiplexers MD1 to MD24 of the fourth group may be constituted with a 2:1 multiplexer. Accordingly, each of the first to twenty-fourth multiplexers MD1 to MD24 of the fourth group may have a first input terminal, a second input terminal, a selection terminal, and an output terminal. Each of the first to twenty-fourth multiplexers MD1 to MD24 of the fourth group may output selection data that is transmitted to the selection terminal, among data that is input to the first input terminal and data that is input to the second input terminal, that is, data that is selected based on a value of the fourth bit SFT<3> of the shift data SFT<4:0>, through the output terminal.

The first to twenty-fourth multiplexers MD1 to MD24 of the fourth group may output respective bits of the fourth shifted data D_SFT4<23:0> that are output by the fourth shift array 140. Among the first to twenty-fourth multiplexers MD1 to MD24 of the fourth group, the first multiplexer MD1 may output the first bit D_SFT4<0> of the fourth shifted data D_SFT4<23:0> that are output by the fourth shift array 140. The second multiplexer MD2 may output the second bit D_SFT4<1> of the fourth shifted data D_SFT4<23:0>. The third multiplexer MD3 may output the third bit D_SFT4<2> of the fourth shifted data D_SFT4<23:0>. In the same way, the fourth to twenty-fourth multiplexers MD4 to MD24 may also output the fourth bit D_SFT4<3> to twenty-fourth bit D_SFT4<23> of the fourth shifted data D_SFT4<23:0>.

Among the first to twenty-fourth multiplexers MD1 to MD24 of the fourth group, the first multiplexer MD1 may receive “0” through the first input terminal. The second multiplexer MD2 may receive the first bit D_SFT3<0> of the third shifted data D_SFT3<22:0> through the first input terminal. The third multiplexer MD3 may receive the second bit D_SFT3<1> of the third shifted data D_SFT3<22:0> through the first input terminal. In the same way, the fourth to twenty-fourth multiplexers MD4 to MD24 may receive the third bit D_SFT3<2> to twenty-third bit D_SFT3<22> of the third shifted data D_SFT3<22:0> through the first input terminals. That is, the second to twenty-fourth multiplexers MD2 to MD24 except the first multiplexer MD1, among the first to twenty-fourth multiplexers MD1 to MD24 of the fourth group, may receive bits of the third shifted data D_SFT3<22:0> through the first input terminals, respectively.

Among the first to twenty-fourth multiplexers MD1 to MD24 of the fourth group, the first multiplexer MD1 may receive the eighth bit D_SFT3<7> of the third shifted data D_SFT3<22:0> through the second input terminal. The second multiplexer MD2 may receive the ninth bit D_SFT3<8> of the third shifted data D_SFT3<22:0> through the second input terminal. The third multiplexer MD3 may receive the tenth bit D_SFT3<9> of the third shifted data D_SFT3<22:0> through the second input terminal. In the same way, the fourth to sixteenth multiplexers MD4 to MD16 may receive the eleventh bit D_SFT3<10> to twenty-third bit D_SFT3<22> of the third shifted data D_SFT3<22:0> through the second input terminals, respectively. The seventeenth to twenty-fourth multiplexers MD17 to MD24 may receive the sign data SIGN<0> through the respective second input terminals. That is, the first to sixteenth multiplexers MD1 to MD16 except the seventeenth to twenty-fourth multiplexers MD17 to MD24, among the first to twenty-fourth multiplexers MD1 to MD4 of the fourth group, may receive the eighth bit D_SFT3<7> to twenty-third bit D_SFT3<22> of the third shifted data D_SFT3<22:0> through the second input terminals.

The first to twenty-fourth multiplexers MD1 to MD24 of the fourth group may receive the fourth bit SFT<3> of the shift data SFT<4:0> in common through the selection terminals. When the fourth bit SFT<3> of the shift data SFT<4:0> is “0”, all of the first to twenty-fourth multiplexers MD1 to MD24 of the fourth group may output data that are input through the first input terminals. In this case, the fourth shift array 140 may additionally output only the lowest 1 bit having a value of “0”, and may output the third shifted data D_SFT3<22:0>, that is, input data, without any change without shifting the third shifted data D_SFT3<22:0>. Specifically, the third shifted data D_SFT3<22:0> that are input through the first input terminals of the second to twenty-fourth multiplexers MD2 to MD24 may be output as the second bit D_SFT3<1> to twenty-fourth bit D_SFT3<23> of the fourth shifted data D_SFT4<23:0> through the output terminals of the second to twenty-fourth multiplexers MD2 to MD24. Furthermore, “0” that is input to the first input terminal of the first multiplexer MD1 may be output as the first bit D_SFT4<0> of the fourth shifted data D_SFT4<23:0> through the output terminal of the first multiplexer MD1.

When the fourth bit SFT<3> of the shift data SFT<4:0> is “1”, all of the first to twenty-fourth multiplexers MD1 to MD24 of the fourth group may output data that are input through the second input terminals. In this case, the fourth shift array 140 may output the third shifted data D_SFT3<22:0> by shifting the third shifted data D_SFT3<22:0> by 8 bits corresponding to a fourth shift bit. Specifically, the eighth bit D_SFT3<7> to twenty-third bit D_SFT3<22> of the third shifted data D_SFT3<22:0> that are input through the second input terminals of the first to sixteenth multiplexers MD1 to MD16 of the fourth group may be output as the first bit D_SFT4<0> to sixteenth bit D_SFT4<15> of the fourth shifted data D_SFT4<23:0> through the output terminals of the first to sixteenth multiplexers MD1 to MD16. Furthermore, the sign data SIGN<0> that is input to the second input terminals of the seventeenth to twenty-fourth multiplexers MD17 to MD24 may be output as the seventeenth bit D_SFT4<16> to twenty-fourth bit D_SFT4<23> of the fourth shifted data D_SFT4<23:0> through the output terminals of the seventeenth to twenty-fourth multiplexers MD17 to MD24.

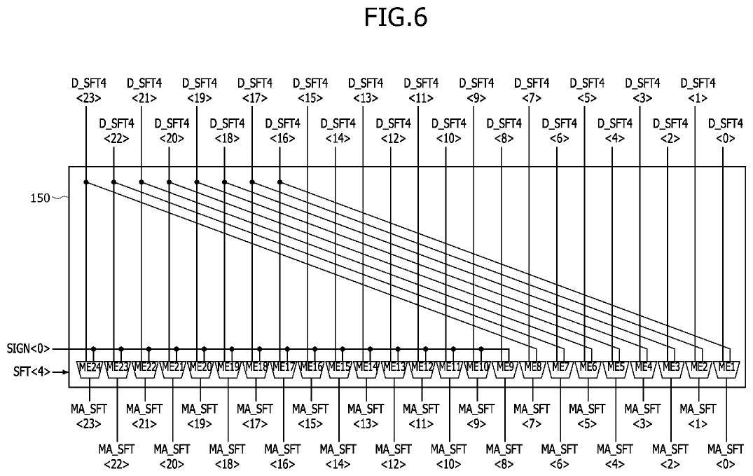

FIG. 6 is a circuit diagram illustrating a construction of the fifth shift array 150 of the shift array circuit 100 in FIG. 1. Referring to FIG. 6, the fifth shift array 150 may be disposed after the fifth (i.e., last) stage of the shift array circuit 100, that is, the fourth shift array 140. The fifth shift array 150 may include a plurality of multiplexers ME1 to ME24. The number of multiplexers ME1 to ME24 that constitutes the fifth shift array 150 may be the same as the number “24” of bits of the shifted mantissa data MA_SFT<23:0> that are finally output by the shift array circuit 100. Hereinafter, the first to twenty-fourth multiplexers ME1 to ME24 that constitute the fifth shift array 150 may be denoted as a fifth group of the first to twenty-fourth multiplexers ME1 to ME24. Each of the first to twenty-fourth multiplexers ME1 to ME24 of the fifth group may be constituted with a 2:1 multiplexer. Accordingly, each of the first to twenty-fourth multiplexers ME1 to ME24 of the fifth group may have a first input terminal, a second input terminal, a selection terminal, and an output terminal. Each of the first to twenty-fourth multiplexers ME1 to ME24 of the fifth group may output selection data that is transmitted to the selection terminal, among data that is input to the first input terminal and data that is input to the second input terminal, that is, data that is selected based on a value of the fifth bit SFT<4> of the shift data SFT<4:0>, through the output terminal.

The first to twenty-fourth multiplexers ME1 to ME24 of the fifth group may output respective bits of the shifted mantissa data MA_SFT<23:0> that are output by the fifth shift array 150. Among the first to twenty-fourth multiplexers ME1 to ME24 of the fifth group, the first multiplexer ME1 may output the first bit MA_SFT<0> of the shifted mantissa data MA_SFT<23:0> that are output by the fifth shift array 150. The second multiplexer ME2 may output the second bit MA_SFT<1> of the shifted mantissa data MA_SFT<23:0>. The third multiplexer ME3 may output the third bit MA_SFT<2> of the shifted mantissa data MA_SFT<23:0>. In the same way, the fourth to twenty-fourth multiplexers ME4 to ME24 may also output the fourth to twenty-fourth bits MA_SFT<23:3> of the shifted mantissa data MA_SFT<23:0>, respectively.

Among the first to twenty-fourth multiplexers ME1 to ME24 of the fifth group, the first multiplexer ME1 may receive the first bit D_SFT4<0> of the fourth shifted data D_SFT4<23:0> through the first input terminal. The second multiplexer ME2 may receive the second bit D_SFT4<1> of the fourth shifted data D_SFT4<23:0> through the first input terminal. The third multiplexer ME3 may receive the third bit D_SFT4<2> of the fourth shifted data D_SFT4<23:0> through the first input terminal. In the same way, the fourth to twenty-fourth multiplexers ME4 to ME24 may receive the fourth bit D_SFT4<3> to twenty-fourth bit D_SFT4<23> of the fourth shifted data D_SFT4<23:0> through the first input terminals. That is, the first to twenty-fourth multiplexers ME1 to ME24 of the fifth group may receive bits of the fourth shifted data D_SFT4<23:0> through the first input terminals, respectively.

Among the first to twenty-fourth multiplexers ME1 to ME24 of the fifth group, the first multiplexer ME1 may receive the seventeenth bit D_SFT4<16> of the fourth shifted data D_SFT4<23:0> through the second input terminal. The second multiplexer ME2 may receive the eighteenth bit D_SFT4<17> of the fourth shifted data D_SFT4<23:0> through the second input terminal. The third multiplexer ME3 may receive the nineteenth bit D_SFT4<18> of the fourth shifted data D_SFT4<23:0> through the second input terminal. In the same way, the fourth to eighth multiplexers ME4 to ME8 may receive the twentieth bit D_SFT4<19> to twenty-fourth bit D_SFT4<23> of the fourth shifted data D_SFT4<23:0> through the second input terminal. Each of the ninth to twenty-fourth multiplexers ME9 to ME24 may receive the sign data SIGN<0> through the second input terminal. That is, the first to eighth multiplexers ME1 to ME8 except the ninth to twenty-fourth multiplexers ME9 to ME24, among the first to twenty-fourth multiplexers ME1 to ME24 of the fifth group, may receive the seventeenth bit D_SFT4<16> to twenty-fourth bit D_SFT4<23> of the fourth shifted data D_SFT4<23:0> through the second input terminals.

The first to twenty-fourth multiplexers ME1 to ME24 of the fifth group may receive the fifth bit SFT<4> of the shift data SFT<4:0> in common through the selection terminals. When the fifth bit SFT<4> of the shift data SFT<4:0> is “0”, all of the first to twenty-fourth multiplexers ME1 to ME24 of the fifth group may output data that are input through the first input terminals. In this case, the fifth shift array 150 may output the fourth shifted data D_SFT4<23:0>, that is, input data, without any change without shifting the fourth shifted data D_SFT4<23:0>. That is, the fourth shifted data D_SFT4<23:0> that are input through the first input terminals of the first to twenty-fourth multiplexers ME1 to ME24 may be output as the shifted mantissa data MA_SFT<23:0> through the output terminals of the first to twenty-fourth multiplexers ME1 to ME24.

When the fifth bit SFT<4> of the shift data SFT<4:0> is “1”, all of the first to twenty-fourth multiplexers ME1 to ME24 of the fifth group may output data that are input through the second input terminals. In this case, the fifth shift array 150 may output the fourth shifted data D_SFT4<23:0>, that is, input data, by shifting the fourth shifted data D_SFT4<23:0> by 16 bits corresponding to a fifth shift bit. Specifically, the seventeenth to twenty-fourth bits D_SFT4<23:16> of the fourth shifted data D_SFT4<23:0> that are input through the second input terminals of the first to eighth multiplexers ME1 to ME8 may be output as the first bit MA_SFT<0> to eighth bit MA_SFT<7> of the shifted mantissa data MA_SFT<23:0> through the output terminals of the first to eighth multiplexers ME1 to ME8. Furthermore, the sign data SIGN<0> that is input to the second input terminals of the ninth to twenty-fourth multiplexers ME9 to ME24 may be output as the ninth bit MA_SFT<8> to twenty-fourth bit MA_SFT<23> of the shifted mantissa data MA_SFT<23:0> through the output terminals of the ninth to twenty-fourth multiplexers ME9 to ME24.

As described with reference to FIGS. 2 to 6, after the first shift operation in the first shift array 110 is performed, the second shift operation in the second shift array 120 may be performed. In the same manner, the third shift operation in the third shift array 130, the fourth shift operation in the fourth shift array 140, and the fifth shift operation in the fifth shift array 150 may be sequentially performed. Because each of the first to fifth shift arrays 110 to 150 directly receives one of the bits of the shift data SFT<4:0> as selection data, a shift operation time can be reduced by the time taken for decoding compared to a case in which shift data is decoded and the decoded data is provided to the multiplexers as selection data. Furthermore, a shift operation in the shift array circuit 100 is started from a time point at which the first bit SFT<0> of the shift data SFT<4:0> is input without a need to wait for the input of all the bits of the shift data SFT<4:0>. Furthermore, because each of the first to fifth shift arrays 110 to 150 that constitute the shift array circuit 100 is constituted with a 2:1 multiplexer, a total area of the shift array circuit can be reduced, and the delay of data processing speed and power consumption attributable to fan-out can be suppressed.

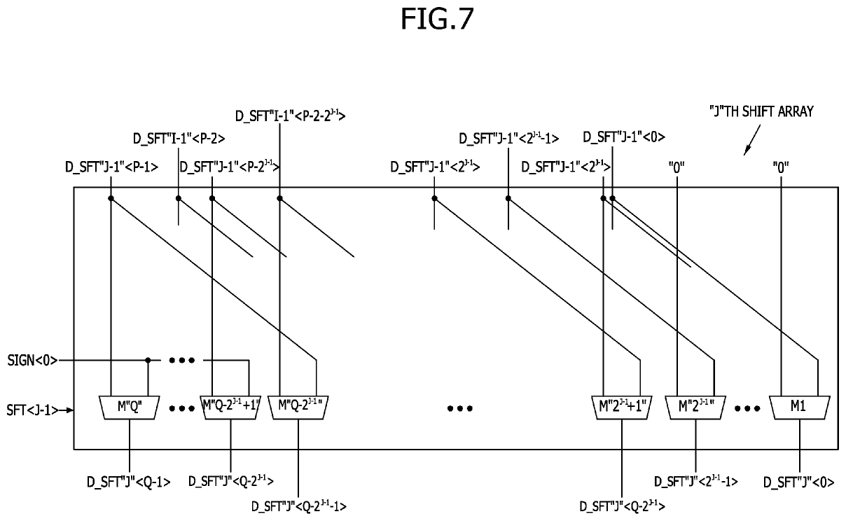

FIG. 7 is a diagram illustrated to describe an example of a common rule that is applied to a shift array that constitutes a shift array circuit according to an embodiment of the present disclosure. A description according to this example may be applied to the remaining shift arrays except a shift array that is disposed in the last stage of the shift array circuit.

Referring to FIG. 7, when “J” is a natural number from “1” to “K−1”, a “J”-th shift array, among “K−1” shift arrays, may receive (“J−1”)-th shifted data D_SFT“J−1”<P−1:0> of “P” bits that are output by a (“J−1”)-th shift array. Although omitted in this drawing, when “J” is “1”, that is, a first shift array that is disposed in the first stage of a shift array circuit may directly receive input data of the shift array circuit. A “J”-th shift bit in the “J”-th shift array becomes a binary weight of a “J”-th bit SFT<J−1> of shift data SFT that is transmitted to the “J”-th shift array, that is, “2^{J-1}”.

When “P+2^{J-1}”, that is, a sum value obtained by adding the number “P” of bits of the (“J−1”)-th shifted data D_SFT“J−1”<P−1:0> and the shift bit “2^{J-1}”, is smaller than the number “M” of bits of shifted mantissa data MA_SFT<M−1:0> that are output by the shift array circuit, the number “Q” of bits of the “J”-th shifted data D_SFT“J”<Q−1:0> that are output by the “J”-th shift array may be the same as “P+2^{J-1}”. Accordingly, the number of multiplexers that constitutes the “J”-th shift array also becomes “Q”, that is, the number of bits of the “J”-th shifted data D_SFT“J”<Q−1:0> that are output data, that is, P+2^{J-1}”. That is, the “J”-th shift array may be constituted with first to “Q”-th multiplexers M1 to M “Q” of the “J”-th group.

Among the first to “Q”-th multiplexers M1 to M “Q” of the “J”-th group, the first to (“2^{J-1}”)-th multiplexers M1 to M“2^{J-1}” may receive “0” that is input to the “J”-th shift array through first input terminals. (“2^{J-1}+1”)-th to “Q”-th multiplexers M“2^{J-1}+1” to M “Q” may receive the (“J−1”)-th shifted data D_SFT“J−1”<P−1:0> that are input to the “J”-th shift array through first input terminals for each bit. The first to (“Q−2^{J-1}”)-th multiplexers M1 to M“Q−2^{J-1}” may receive the (“J−1”)-th shifted data D_SFT“J−1”<P−1:0> through second input terminals for each bit. The (“Q−2^{J-1}+1”)-th to “Q”-th multiplexers M1 to M “Q” may receive sign data SIGN<0> of floating-point data in common through second input terminals.

When the “J”-th bit SFT<J−1> of the shift data SFT is “0”, the first to “Q”-th multiplexers M1 to M“Q” may output data that are transmitted to the first input terminals, through output terminals. Specifically, the first to (“2^{J-1}”)-th multiplexers M1 to M“2^{J-1}” may output “0” as a first bit D_SFT“J”<0> to (“2^{J-1}”)-th bit D_SFT“J”<2^{J-1}−1> of the “J”-th shifted data D_SFT“J”<Q−1:0> through output terminals. Furthermore, the (“2^{J-1}+1”)-th to “Q”-th multiplexers M“2^{J-1}+1” to M “Q” may output the (“J−1”)-th shifted data D_SFT“J−1<P−1:0> as the (“2^{J-1}+1”)-th bit D_SFT“J”<2^{J-1}> to “Q”-th bit D_SFT“J”<Q−1> of the “J”-th shifted data D_SFT“J”<Q−1:0> through output terminals.

When the “J”-th bit SFT<J−1> of the shift data SFT is “1”, the first to “Q”-th multiplexers M1 to M “Q” may output data that are transmitted to the second input terminals, through the output terminals. Specifically, the first to (“Q−2^{J-1}”)-th multiplexers M1 to M“Q−2^{J-1}” may output the (“J−1”)-th shifted data D_SFT“J−1<P−1:0> as first bit D_SFT“J”<0> to (“Q−2^{J-1}”)-th bit D_SFT“J”<Q−2^{J-1}−1> of the “J”-th shifted data D_SFT“J”<Q−1:0> through the output terminals. Furthermore, the (“2^{J-1}+1”)-th to “Q”-th multiplexers M“2^{J-1}+1”-M “Q” may output the sign data SIGN<0> as a (“2^{J-1}+1”)-th bit D_SFT“J”<2^{J-1}> to “Q”-th bit D_SFT“J”<Q−1> of the “J”-th shifted data D_SFT“J”<Q−1:0> through the output terminals.

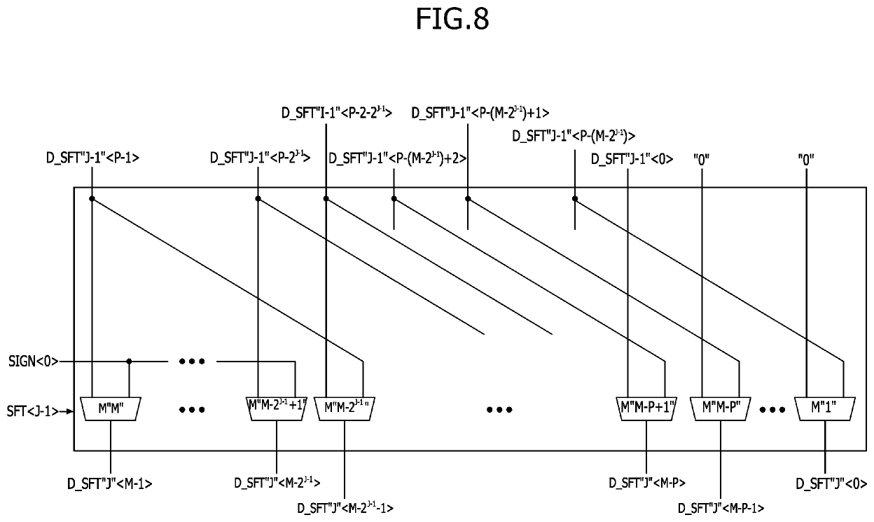

FIG. 8 is a diagram illustrated to describe another example of the common rule that is applied to a shift array that constitutes a shift array circuit according to an embodiment of the present disclosure. A description according to this example may be applied to the remaining shift arrays except a shift array that is disposed in the last stage of the shift array circuit.

Referring to FIG. 8, when “J” is a natural number from “2” to “K−1”, a “J”-th shift array, among “K−2” shift arrays, may receive (“J−1”)-th shifted data D_SFT“J−1”<P−1:0> of “P” bits that are output by a (“J−1”)-th shift array. A “J”-th shift bit in the “J”-th shift array becomes a binary weight of a “J”-th bit SFT<J−1> of shift data SFT<K−1:0> that are transmitted to the “J”-th shift array, that is, “2^{J-1}”.

The “J”-th shift array may output “J”-th shifted data D_SFT“J”<Q−1:0> of “Q” bits. When “P+2^{J-1}”, that is, a sum value that is obtained by adding the number “P” of bits of (“J−1”)-th shifted data D_SFT“J−1”<P−1:0> and the shift bit “2^{J-1}”, is equal to or greater than the number “M” of bits of shifted mantissa data MA_SFT<M−1:0> that are output by the shift array circuit, the number “Q” of bits of the “J”-th shifted data D_SFT“J”<Q−1:0> that are output by the “J”-th shift array is the same as the number “M” of bits of the shifted mantissa data MA_SFT<M−1:0>. Furthermore, the number of multiplexers that constitutes the “J”-th shift array is the same as the number “Q” of bits of the “J”-th shifted data D_SFT“J”<Q−1:0>, that is, “M”. That is, the “J”-th shift array may be constituted with first to “M”-th multiplexers M1 to M“M” of a “J”-th group.

The first to (“M−P”)-th multiplexers M1 to M“M−P”, among the first to “M”-th multiplexers M1 to M“M” of the “J”-th group, may receive “0” that is input to the “J”-th shift array in common through first input terminals. The remaining multiplexers, that is, the (“M−P+1”)-th to “M”-th multiplexers M“M−P+1” to M“M”, among the first to “M”-th multiplexers M1 to M“M” of the “J”-th group, may receive a first bit D_SFT“J−1”<0> to “P”-th bit D_SFT“J−1”<P−1> of the (“J−1”)-th shifted data D_SFT“J−1”<P−1:0> that are input to the “J”-th shift array through first input terminals for each bit. Furthermore, the first to (“M−2^{J-1}”)-th multiplexers M1 to M“M−2^{J-1}” may receive a (“P−(M−2^{J-1})+1”)-th bit D_SFT“J−1”<P−(M−2^{J-1})> to “P”-th bit D_SFT“J−1”<P−1)> of the (“J−1”)-th shifted data D_SFT“J−1”<P−1:0> through second input terminals for each bit. The (“M−2^{J-1}”)-th to “M”-th multiplexers M“M−2^{J-1}+1” to M“M” may receive sign data SIGN<0> of floating-point data in common through second input terminals.

When the “J”-th bit SFT<J−1> of the shift data SFT is “0”, the first to “M”-th multiplexers M1 to M“M” may output data that are transmitted to the first input terminals through output terminals. Specifically, the first to (“M−P”)-th multiplexers M1 to M“M−P” may output “0” as first bit D_SFT“J”<0> to (“M−P”)-th bit D_SFT“J”<M−P> of the “J”-th shifted data D_SFT“J”<Q−1:0> through output terminals. Furthermore, the (“M−P+1”)-th to “M”-th multiplexers M“M−P+1” to M“M” may output (“J−1”)-th shifted data D_SFT“J−1<P−1:0> as (“M−P+1”)-th bit D_SFT“J”<M−P> to “M”-th bit D_SFT“J”<M−1> of the “J”-th shifted data D_SFT“J”<Q−1:0> through output terminals.

When the “J”-th bit SFT<J−1> of the shift data SFT is “1”, the first to “M”-th multiplexers M1 to M“M” may output data that are transmitted to the second input terminals through output terminals. Specifically, the first to (“M−2^{J-1}”)-th multiplexers M1 to M“M−2^{J-1}” may output a (“P−(M−2^{J-1})+1”)-th bit D_SFT“J−1”<P−(M−2^{J-1})> to “P”-th bit D_SFT“J−1”<P−1> of the (“J−1”)-th shifted data D_SFT“J−1”<P−1:0> as a first bit D_SFT“J”<0> to (“M−2^{J-1}”)-th bit D_SFT“J”<M−2^{J-1}-1> of the “J”-th shifted data D_SFT“J”<M−1:0> through output terminals. Furthermore, the (“M−2^{J-1}+1”)-th to “M”-th multiplexers M“M−2^{J-1}+1” to M“M” may output the sign data SIGN<0> as a (“M−2^{J-1}+1”)-th bit D_SFT“J”<M−2^{J-1}> to “M”-th bit D_SFT“J”<M−1> of the “J”-th shifted data D_SFT“J”<Q−1:0> through output terminals.

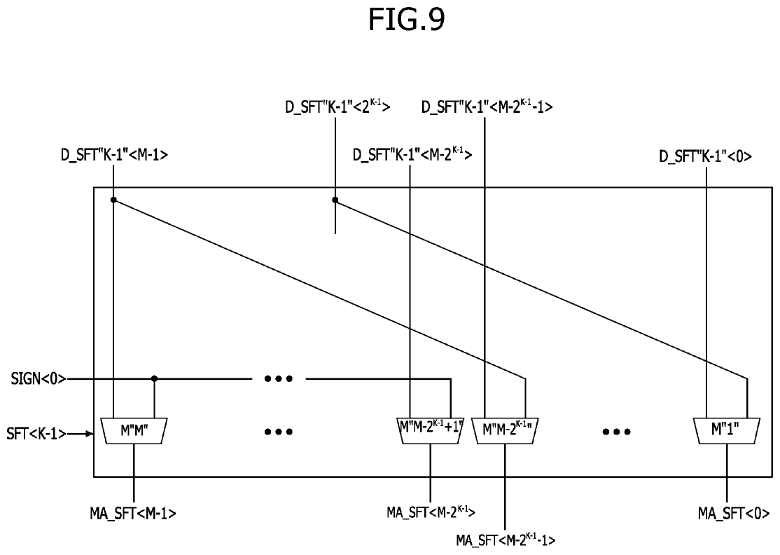

FIG. 9 is a diagram illustrated to describe still another example of the common rule that is applied to a shift array that constitutes a shift array circuit according to an embodiment of the present disclosure.

Referring to FIG. 9, a “K”-th shift array that is disposed in the last stage of a shift array circuit may receive (“K−1”)-th shifted data D_SFT“K−1”<M−1:0> of “M” bits that are output by a (“K−1”)-th shift array. Furthermore, the “K”-th shift array may output shifted mantissa data MA_SFT<M−1:0> of “M” bits. A “K”-th shift bit in the “K”-th shift array becomes a binary weight of a “K”-th bit SFT<K−1> of the shift data SFT<K−1:0> that are transmitted to the “K”-th shift array, that is, “2^{K-1}”. The “K”-th shift array may be constituted with first to “M”-th multiplexers M1 to M“M” of a “K”-th group.

The first to “M”-th multiplexers M1 to M“M” of the “K”-th group may receive the (“K−1”)-th shifted data D_SFT“K−1”<M−1:0> that are input to the “K”-th shift array through first input terminals for each bit. The first to (“M−2^{K-1}”)-th multiplexers M1 to M“M−2^{K-1}” may receive (“2^{K-1}+1”)-th bit D_SFT“K−1”<2^{K-1}> to “M”-th bit D_SFT“K−1”<M−1> of the (“K−1”)-th shifted data D_SFT“K−1”<M−1:0> through second input terminals for each bit. The (“M−2^{K-1}+1”)-th to “M”-th multiplexers M“M−2^{K-1}+1” to M“M” may receive sign data SIGN<0> of floating-point data in common through the second input terminals.

When the “K”-th bit SFT<K−1> of the shift data SFT is “0”, the first to “M”-th multiplexers M1 to M“M” may output data that are transmitted to the first input terminals, through output terminals. Specifically, the first to “M”-th multiplexers M1 to M“M” may output the (“K−1”)-th shifted data D_SFT“K−1<M−1:0> as shifted mantissa data MA_SFT<M−1:0> through output terminals.

When the “K”-th bit SFT<K−1> of the shift data SFT is “1”, the first to “M”-th multiplexers M1 to M“M” may output data that are transmitted to the second input terminals through the output terminals. Specifically, the first to (“M−2^{K-1}”)-th multiplexers M1 to M“M−2^{K-1}” may output the (“2^{K-1}1+1”)-th bit D_SFT“K−1”<2^{K-1}> to “M”-th bit D_SFT“K−1”<M−1> of the (“K−1”)-th shifted data D_SFT“K−1”<M−1:0> as a first bit MA_SFT<0> to (“M−2^{K-1}”)-th bit MA_SFT<M−2^{K-1}−1> of the shifted mantissa data MA_SFT<M−1:0> through the output terminals. Furthermore, the (“M−2^{K-1}1+1”)-th to “M”-th multiplexers M“M−2^{K-1}1+1” to M“M” may output the sign data SIGN<0> as (“M−2^{K-1}1+1”)-th bit MA_SFT<M−2^{K-1}> to “M”-th bit MA_SFT<M−1> of the shifted mantissa data MA_SFT<M−1:0> through the output terminals.

The shift array circuit 100 that has been described with reference to FIGS. 1 to 9 may be used by various arithmetic circuits. For example, the shift array circuit 100 may be used to exclude the use of a floating-point adder in a process of performing multiplication operations on input data having a floating-point format and performing an addition operation on multiplication data that are generated as the results of the multiplication operations. In general, the addition operation for the multiplication data having the floating-point format may be performed by an addition circuit in which a plurality of floating-point adders is disposed in an adder tree form. However, the floating-point adder needs to perform shift processing on mantissa data in order for exponent data of input data to have the same value. Accordingly, when compared to a fixed-point adder, the floating-point adder has a complicated structure and also has a very long operation time. The shift array circuit 100 according to an embodiment of the present disclosure may be disposed between the multiplication circuit and the addition circuit, and may first perform a shift operation on mantissa data of multiplication data so that all exponent data have the same value. Accordingly, in an embodiment, the addition circuit can perform an addition operation on only the mantissa data. Hereinafter, a case in which the shift array circuit 100 is applied to an arithmetic circuit that performs a multiplication and accumulation (hereinafter referred to as “MAC”) operation is described as an example.

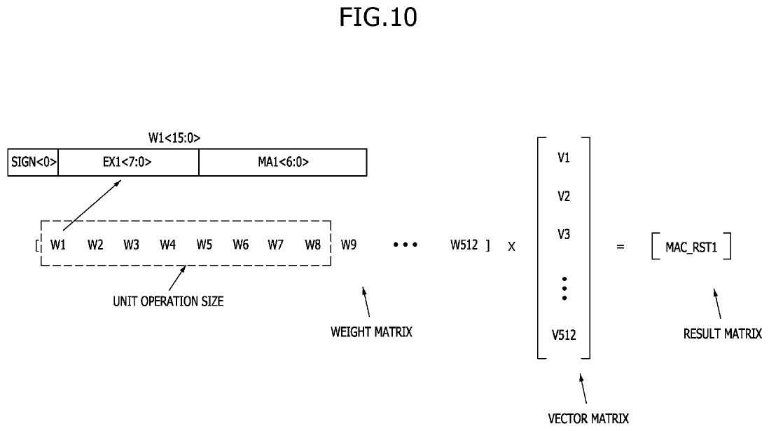

FIG. 10 is a diagram illustrated to describe an example of an MAC operation that is performed in an arithmetic circuit according to an example of the present disclosure and a floating-point format of weight data.

Referring to FIG. 10, the MAC operation may be performed as a process of generating a result matrix by performing matrix multiplication on a weight matrix and a vector matrix. The weight matrix may have a plurality of, for example, 512 weight data W1 to W512 as row elements. The vector matrix may have a plurality of, for example, 512 vector data V1 to V512 as column elements. The result matrix may have MAC result data MAC_RST1 as an element. The weight data W“F” of an “F”-th column (“F” is 1, 2 to 512) of the weight matrix may be multiplied by the vector data V“F” of the “F”-th row of the vector matrix. Accordingly, 512 multiplication data W“F”×V“F” may be generated. If all of the 512 multiplication data are added, the MAC result data MAC_RST1 may be generated.

Each of the weight data W1 to W512 and each of the vector data V1 to V512 may have a floating-point format. It is presupposed that each of the weight data W1 to W512 and each of the vector data V1 to V512 have a 16-bit brain floating-point (hereinafter referred to as BF16) format. Accordingly, for example, the weight data (hereinafter referred to as first weight data) W1 of the first row and first column of the weight matrix may be constituted with first sign data SIGN1<0> of 1 bit, first exponent data EX1<7:0> of 8 bits, and first mantissa data MA1<6:0> of 7 bits. Although not illustrated in FIG. 10, each of the remaining second to 512^{th} weight data W2 to W512 may be identically constituted with sign data of 1 bit, exponent data of 8 bits, and mantissa data of 7 bits. Furthermore, each of the first to 512^{th} vector data V1 to V512 of the vector matrix may also be identically constituted with sign data of 1 bit, exponent data of 8 bits, and mantissa data of 7 bits.

As in the weight matrix of FIG. 10, if the number of weight data W1 to W512 on which matrix multiplication will be performed is greater than a unit operation size of an arithmetic circuit that performs an MAC operation, the MAC result data MAC_RST1 might not be generated through one MAC operation. In this case, the “unit operation size” may mean the size of the weight data W which may be processed by the arithmetic circuit through one MAC operation. Hereinafter, it is presupposed that the unit operation size of the arithmetic circuit is 128 bits. Because each of the weight data W1 to W512 has the 16-bit floating-point format, one MAC operation may be performed on eight weight data and eight vector data. That is, as the MAC operation is repeatedly performed on the eight weight data and the eight vector data 64 times, the MAC result data MAC_RST1 may be generated.

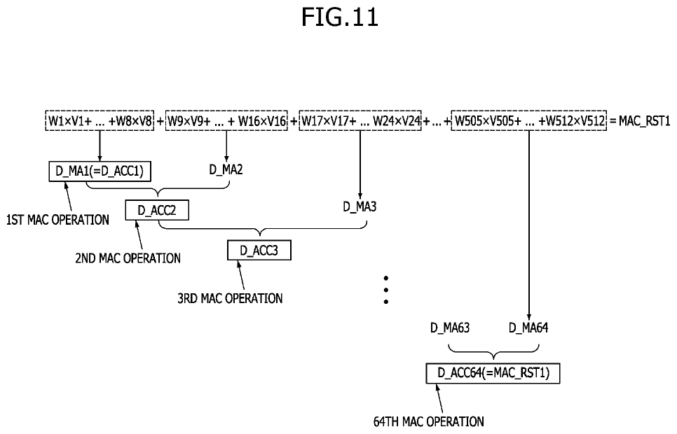

FIG. 11 is a diagram illustrated to describe a process of the matrix multiplication in FIG. 10 being performed in the arithmetic circuit in which the unit operation size is 128 bits.

Referring to FIG. 11, in order to generate the MAC result data MAC_RST1, first to sixty-fourth MAC operations may be sequentially performed. Each of the first to sixty-fourth MAC operations may be performed on the eight weight data and the eight vector data. Hereinafter, data that are generated by the first to sixty-fourth MAC operations may be denoted as first to sixty-fourth accumulation data D_ACC1 to D_ACC64, respectively. As illustrated in this drawing, the first accumulation data D_MAC1 may be generated by the first MAC operation. The second accumulation data D_ACC2 may be generated by the second MAC operation. The third accumulation data D_ACC3 may be generated by the third MAC operation. Similarly, the sixty-fourth accumulation data D_ACC64 may be generated by the sixty-fourth MAC operation.

Each of the first to sixty-fourth MAC operations may include a multiplication/addition operation and an accumulation operation. First, in the process of performing the first to sixty-fourth MAC operations, first to sixty-fourth multiplication addition data D_MA1 to D_MA64 may be generated by the multiplication/addition operations. Next, accumulation data D_ACC may be generated by accumulating multiplication addition data D_MA that is generated by a multiplication/addition operation and accumulation data D_ACC that is generated by a previous MAC operation. The sixty-fourth accumulation data D_ACC64 that is generated by the accumulation operation of the last MAC operation, that is, the sixty-fourth MAC operation may correspond to the MAC result data MAC_RST1.

Specifically, the first MAC operation process may be performed as follows. First, the first multiplication addition data D_MA1 may be generated by performing a multiplication/addition operation on the first to eighth weight data W1 to W8 and the first to eighth vector data V1 to V8. Next, MAC data that is generated in a previous MAC operation needs to be accumulated in the first multiplication addition data D_MA1. Because accumulation data that is generated by the previous MAC operation is not present, the first multiplication addition data D_MA1 becomes the first accumulation data D_ACC1. The second MAC operation process may be performed as follows. First, the second multiplication addition data D_MA2 may be generated by performing a multiplication/addition operation on the ninth to sixteenth weight data W9 to W16 and the ninth to sixteenth vector data V9 to V16. Next, the second accumulation data D_ACC2 may be generated by accumulating the first accumulation data D_ACC1 in the second multiplication addition data D_MA2. The third MAC operation process may be performed as follows. First, the third multiplication addition data D_MA3 may be generated by performing a multiplication/addition operation on the seventeenth to twenty-fourth weight data W17 to W24 and the seventeenth to twenty-fourth vector data V17 to V24. Next, the third accumulation data D_ACC3 may be generated by accumulating the second accumulation data D_ACC2 in the third multiplication addition data D_MA3. The remaining MAC operations are performed in the same way. Accordingly, the sixty-fourth MAC operation may be performed as follows. First, the sixty-fourth multiplication addition data D_MA64 may be generated by performing a multiplication/addition operation on the 505^{th} to 512^{th} weight data W505 to W512 and the 505^{th} to 512^{th} vector data V505 to V512. Next, the sixty-fourth accumulation data D_ACC64 may be generated by accumulating the sixty-third accumulation data D_ACC63 in the sixty-fourth multiplication addition data D_MA64. The sixty-fourth accumulation data D_ACC64 may constitute the MAC result data MAC_RST1.

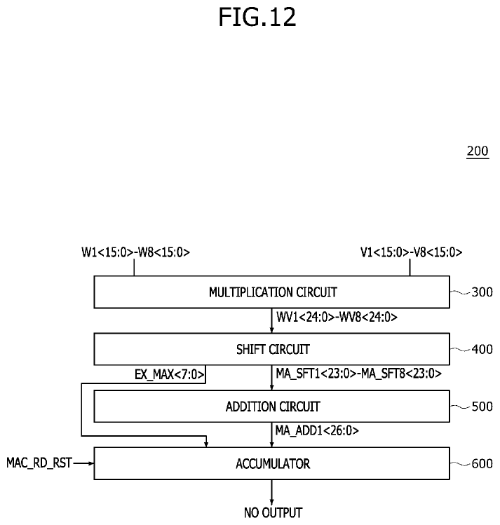

FIG. 12 is a block diagram illustrating an arithmetic circuit 200 according to an example of the present disclosure. The arithmetic circuit 200 according to this example may perform the matrix multiplication operation that has been described with reference to FIGS. 10 and 11. That is, the arithmetic circuit 200 may perform the multiplication operations on weight data and vector data having the floating-point format. Next, the arithmetic circuit 200 may perform the addition operation on multiplication data that are generated as the results of the multiplication operations. Next, the arithmetic circuit 200 may perform the accumulation operation on addition data that is generated by the addition operation and previous MAC data. Hereinafter, it is presupposed that a unit operation size of the arithmetic circuit 200 is 128 bit as described with reference to FIGS. 10 and 11. Furthermore, it is presupposed that each of the weight data and the vector data has a 16-bit BF16 format.

Referring to FIG. 12, the arithmetic circuit 200 may include a multiplication circuit 300, a shift circuit 400, an addition circuit 500, and an accumulator 600. The multiplication circuit 300 may receive the first to eighth weight data W1<15:0> to W8<15:0> and the first to eighth vector data V1<15:0> to V8<15:0>. Each of the weight data W1<15:0> to W8<15:0> and the vector data V1<15:0> to V8<15:0> may be constituted with sign data of 1 bit, exponent data of 8 bits, and mantissa data of 7 bits. The mantissa data of each of the weight data W1<15:0> to W8<15:0> and the vector data V1<15:0> to V8<15:0> may have an implied bit (i.e., “1”, that is, a left number of a binary digit point) added thereto, and may be input to the multiplication circuit 300 as an 8-bit size. The multiplication circuit 300 may output first to eighth multiplication data WV1<24:0> to WV8<24:0> by performing multiplication operations on the first to eighth weight data W1<15:0> to W8<15:0> and the first to eighth vector data V1<15:0> to V8<15:0>. The first to eighth multiplication data WV1<24:0> to WV8<24:0> may be constituted with first to eighth sign data each having 1 bit, first to eighth exponent data each having 8 bits, and first to eighth mantissa data each having 16 bits, respectively.

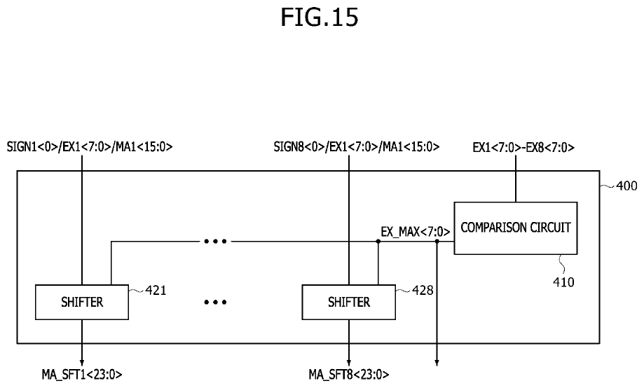

The shift circuit 400 may receive the first to eighth multiplication data WV1<24:0> to WV8<24:0> from the multiplication circuit 300. Also, although not shown in the FIG. 12, the shift circuit 400 may receive first to eighth sign data SIGN1<0> to SIGN8<0> from the multiplication circuit 300. The shift circuit 400 may detect maximum exponent data among the first to eighth exponent data of the first to eighth multiplication data WV1<24:0> to WV8<24:0>. The shift circuit 400 may generate first to eighth shifted mantissa data MA_SFT1<23:0> to MA_SFT8<23:0> by performing shift operations on first to eighth mantissa data by the number of bits (i.e., a shift bit) that corresponds to a difference between the maximum exponent data and the first to eighth exponent data. The shift circuit 400 may output maximum exponent data EX_MAX<7:0> having 8 bits, and first to eighth shifted mantissa data MA_SFT1<23:0> to MA_SFT8<23:0> each having 24 bits. The shift circuit 400 will be more specifically described below with reference to FIGS. 15 to 17.

The addition circuit 500 may perform an addition operation of adding up all of the first to eighth shifted mantissa data MA_SFT1<23:0> to MA_SFT8<23:0> that are transmitted by the shift circuit 400. The addition circuit 500 may be constructed by disposing a plurality of fixed-point adders in an adder tree form. The addition circuit 500 may generate and output first mantissa data MA_ADD1<26:0> as the results of the addition operation. The first mantissa data MA_ADD1<26:0> may have the number of bits that has been more increased than the number of bits of input data due to a carry bit that is generated in the addition operation process of the addition circuit 500. In this example, it is presupposed that the number of bits of the first mantissa data MA_ADD1<26:0> has a 27-bit size that has been further increased by 3 bits in the addition operation process of the addition circuit 500.

The accumulator 600 may receive the maximum exponent data EX_MAX<7:0> that are output by the shift circuit 400. Furthermore, the accumulator 600 may receive the first mantissa data MA_ADD1<26:0> that are output by the addition circuit 500. The maximum exponent data EX_MAX<7:0> and the first mantissa data MA_ADD1<26:0> may constitute the first multiplication addition data (D_MA1 in FIG. 11). The accumulator 600 may generate the first accumulation data D_ACC1 by performing an accumulation operation on the first multiplication addition data D_MA1 and latch data (i.e., accumulation data that is generated by a previous MAC operation) that has been latched in the accumulator 600. In the case of the first MAC operation, because the latch data is “0”, the first multiplication addition data D_MA1 becomes the first accumulation data D_ACC1. The accumulator 600 may perform normalization on the first accumulation data D_ACC1.

The accumulator 600 may receive an MAC result read control signal MAC_RD_RST. When the final MAC result data MAC_RST1, that is, the sixty-fourth accumulation data (i.e., D_ACC64 in FIG. 11), is generated, the MAC result read control signal MAC_RD_RST having a first logic level, for example, a high level, may be transmitted to the accumulator 600. The accumulator 600 may output the sixty-fourth accumulation data D_ACC64 as the MAC result data MAC_RST1 in response to the MAC result read control signal MAC_RD_RST having the high level. While the first to sixty-third MAC operations are performed, the MAC result read control signal MAC_RD_RST having the low level may be transmitted to the accumulator 600. Accordingly, the accumulator 600 might not output accumulation data.

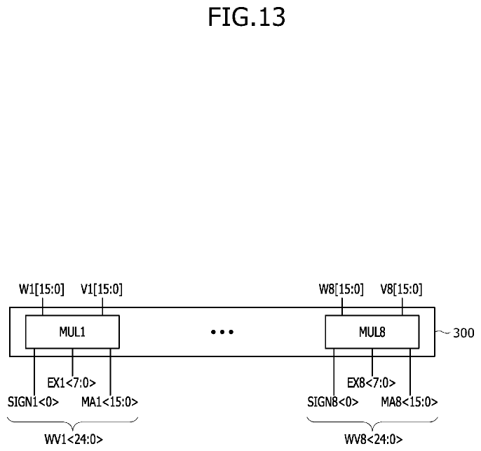

FIG. 13 is a block diagram illustrating an example of the multiplication circuit 300 that is included in the arithmetic circuit 200 of FIG. 12.

Referring to FIG. 13, the multiplication circuit 300 may include first to eighth multipliers MUL1 to MUL8. The first multiplier MUL1 may output the first multiplication data WV1<24:0> of 25 bits by performing a multiplication operation on the first weight data W1<15:0> and the first vector data V1<15:0>. The first multiplication data WV1<24:0> include first sign data SIGN1<0> of 1 bit, first exponent data EX1<7:0> of 8 bits, and first mantissa data MA1<15:0> of 16 bits. Similarly, the eighth multiplier MUL8 may output the eighth multiplication data WV8<24:0> of 25 bits by performing a multiplication operation on the eighth weight data W8<15:0> and the eighth vector data V8<15:0>. The eighth multiplication data WV8<24:0> include eighth sign data SIGN8<0> of 1 bit, eighth exponent data EX8<7:0> of 8 bits, and eighth mantissa data MA8<15:0> of 16 bits. Although the second to seventh multipliers have been omitted in FIG. 13, the second to seventh multipliers may also output second to seventh multiplication data, respectively, in the same manner as the first multiplier MUL1 and the eighth multiplier MUL8.

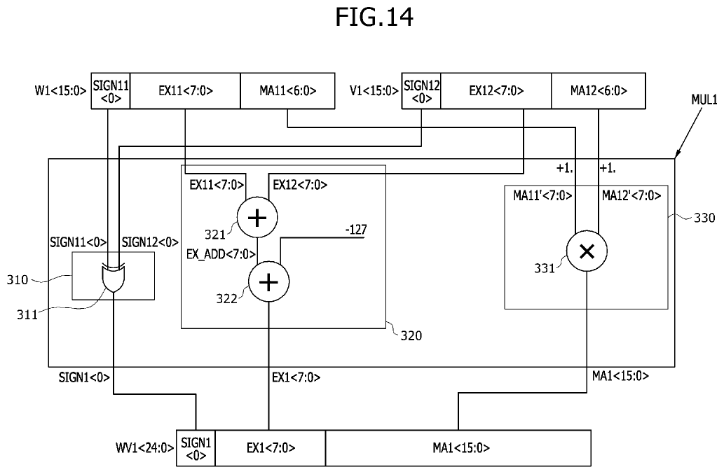

FIG. 14 is a circuit diagram illustrating an example of the first multiplier MUL1 that is included in the multiplication circuit 300 of FIG. 13. Hereinafter, a description of the first multiplier MUL1 may be identically applied to the second to eighth multipliers that are included in the multiplication circuit 300 of FIG. 13.

Referring to FIG. 14, the first weight data W1<15:0> of 16 bits may include sign data SIGN11<0> of 1 bit, exponent data EX11<7:0> of 8 bits, and mantissa data MA11<6:0> of 7 bits. Similarly, the first vector data V1<15:0> may include sign data SIGN12<0> of 1 bit, exponent data EX12<7:0> of 8 bits, and mantissa data MA12<6:0> of 7 bits. The first multiplier MUL1 may include a sign processing circuit 310, an exponent processing circuit 320, and a mantissa processing circuit 330.

The sign processing circuit 310 may include an exclusive OR (hereinafter referred to as “XOR”) gate 311. The sign data SIGN11<0> of the first weight data W1<15:0> may be input to a first input terminal of the XOR gate 311. The sign data SIGN12<0> of the first vector data V1<15:0> may be input to a second input terminal of the XOR gate 311. The XOR gate 311 may output the first sign data SIGN1<0> by performing an XOR operation on the sign data SIGN11<0> of the first weight data W1<15:0> and the sign data SIGN12<0> of the first vector data V1<15:0>. When only any one of the sign data SIGN11<0> of the first weight data W1<15:0> and the sign data SIGN12<0> of the first vector data V1<15:0> indicates “1” (i.e., a negative number), the XOR gate 311 may output “1” as the first sign data SIGN1<0>. In contrast, when both the sign data SIGN11<0> of the first weight data W1<15:0> and the sign data SIGN12<0> of the first vector data V1<15:0> indicate “0” (i.e., a positive number) or indicate “1”, the XOR gate 311 may output “0” as the first sign data SIGN1<0>. The first sign data SIGN1<0> of 1 bit that is output by the XOR gate 311 may constitute sign data of the first multiplication data WV1<24:0>.

The exponent processing circuit 320 may include a first exponent adder 321 and a second exponent adder 322. The first exponent adder 321 may receive the exponent data EX11<7:0> of the first weight data W1<15:0> and the exponent data EX12<7:0> of the first vector data V1<15:0>. The first exponent adder 321 may output exponent addition data EX_ADD<7:0> by adding the exponent data EX11<7:0> of the first weight data W1<15:0> and the exponent data EX12<7:0> of the first vector data V1<15:0>. Because both the exponent data EX11<7:0> of the first weight data W1<15:0> and the exponent data EX12<7:0> of the first vector data V1<15:0> include an exponent bias value, for example, 127, the second exponent adder 322 may perform an operation of subtracting the exponent bias value “127” from the exponent addition data EX_ADD<7:0>, that is, an addition operation on the exponent addition data EX_ADD<7:0> and “−127”. The second exponent adder 322 may output the first exponent data EX1<7:0> of 8 bits as addition result data. The first exponent data EX1<7:0> of 8 bits that are output by the second exponent adder 322 may constitute exponent data of the first multiplication data WV1<24:0>.

The mantissa processing circuit 330 may include a mantissa multiplier 331. The mantissa multiplier 331 may receive mantissa data MA11′<7:0> of the first weight data W1<15:0> and mantissa data MA12′<7:0> of the first vector data V1<15:0>. The mantissa data MA11′<7:0> of the first weight data W1<15:0> may have a format of “1.MA1” because an implied bit is included in the mantissa data MA11<6:0> of the first weight data W1<15:0>. Likewise, the mantissa data MA12′<7:0> of the first vector data V1<15:0> may have a format of “1.MA2” because an implied bit is included in the mantissa data MA12<6:0> of the first vector data V1<15:0>. The mantissa multiplier 331 may output the first mantissa data MA1<15:0> of 16 bits by performing a multiplication operation on the mantissa data MA11′<7:0> of the first weight data W1<15:0> and the mantissa data MA12′<7:0> of the first vector data V1<15:0>. The first mantissa data MA1<15:0> of 16 bits that are output by the mantissa multiplier 331 may constitute mantissa data of the first multiplication data WV1<24:0>.

FIG. 15 is a block diagram illustrating an example of the shift circuit 400 that is included in the arithmetic circuit 200 of FIG. 12. Referring to FIG. 15, the shift circuit 400 may include a comparison circuit 410 and first to eighth shifters 421 to 428. The illustration of the second to seventh shifter has been omitted in FIG. 15.

The comparison circuit 410 may receive the first exponent data EX1<7:0> to the eighth exponent data EX8<7:0> of the first multiplication data WV1<24:0> to eighth multiplication data WV8<24:0> that are output by the multiplication circuit (300 in FIG. 12). The comparison circuit 410 may compare the sizes of the first exponent data EX1<7:0> to the eighth exponent data EX8<7:0>. The comparison circuit 410 may output, as the maximum exponent data EX_MAX<7:0>, exponent data having the greatest value among the first exponent data EX1<7:0> to the eighth exponent data EX8<7:0>. The maximum exponent data EX_MAX<7:0> that are output by the comparison circuit 410 may be transmitted to the first shifter 421 to the eighth shifter 428 in common. Furthermore, the maximum exponent data EX_MAX<7:0> may be transmitted from the shift circuit 400 to the accumulator (600 in FIG. 12).

The first shifter 421 to the eighth shifter 428 may receive the first multiplication data WV1<24:0> to eighth multiplication data WV8<24:0> that are output by the multiplication circuit (300 in FIG. 12). That is, as illustrated in this drawing, the first shifter 421 may receive the first sign data SIGN1<0>, first exponent data EX1<7:0>, and first mantissa data MA1<15:0> of the first multiplication data WV1<24:0>. The eighth shifter 428 may receive the eighth sign data SIGN8<0>, eighth exponent data EX8<7:0>, and eighth mantissa data MA8<15:0> of the eighth multiplication data WV8<24:0>. The first shifter 421 to the eighth shifter 428 may receive the maximum exponent data EX_MAC<7:0> from the comparison circuit 410. The first shifter 421 to the eighth shifter 428 may output first shifted mantissa data MA_SFT1<23:0> to eighth shifted mantissa data MA_SFT8<23:0>, respectively.

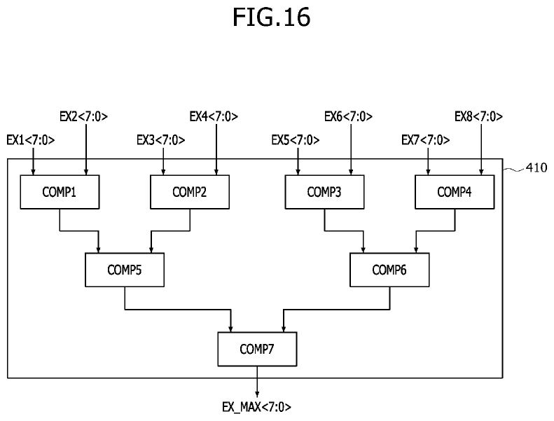

FIG. 16 is a block diagram illustrating an example of the comparison circuit 410 that is included in the shift circuit 400 of FIG. 15.

Referring to FIG. 16, the comparison circuit 410 may include a first comparator COMP1 to a seventh comparator COMP7. The first comparator COMP1 to the seventh comparator COMP7 may have two input terminals and one output terminal. The first comparator COMP1 to the seventh comparator COMP7 may be arranged as a hierarchical structure, such as a tree structure. The first comparator COMP1 to fourth comparator COMP4 may be disposed in a first stage, that is, the highest of the comparison circuit 410. The fifth comparator COMP5 and the sixth comparator COMP6 may be disposed in a second stage below the first stage. The seventh comparator COMP7 may be disposed in a third stage, that is, the lowest of the comparison circuit 410.

The first comparator COMP1 of the first stage receives the first exponent data EX1<7:0> of the first multiplication data WV1<24:0> and the second exponent data EX2<7:0> of the second multiplication data WV2<24:0>. The first comparator COMP1 may output exponent data having a greater value by comparing the first exponent data EX1<7:0> and the second exponent data EX2<7:0>. The second comparator COMP2 of the first stage may output exponent data having a greater value by comparing the third exponent data EX3<7:0> and the fourth exponent data EX4<7:0>. The third comparator COMP3 of the first stage may output exponent data having a greater value by comparing the fifth exponent data EX5<7:0> and the sixth exponent data EX6<7:0>. The fourth comparator COMP4 of the first stage may output exponent data having a greater value by comparing the seventh exponent data EX7<7:0> and the eighth exponent data EX8<7:0>.

The fifth comparator COMP5 of the second stage may output exponent data having a greater value by comparing the exponent data that is output by the first comparator COMP1 and the exponent data that is output by the second comparator COMP2. The sixth comparator COMP6 of the second stage may output exponent data having a greater value by comparing the exponent data that is output by the third comparator COMP3 and the exponent data that is output by the fourth comparator COMP4. The seventh comparator COMP7 of the third stage may output, as the maximum exponent data EX_MAX<7:0>, exponent data having a greater value by comparing the exponent data that is output by the fifth comparator COMP5 and the exponent data that is output by the sixth comparator COMP6. As a result, the comparison circuit 410 may output exponent data having the greatest value, among the first exponent data EX1<7:0> to the eighth exponent data EX8<7:0>, as the maximum exponent data EX_MAX<7:0>.

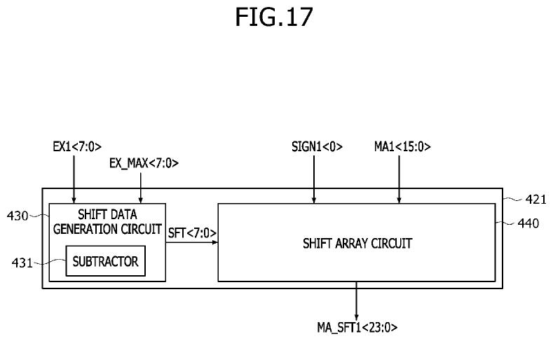

FIG. 17 is a block diagram illustrating an example of the first shifter 421 of the shift circuit 400 in FIG. 15. Hereinafter, a description of the first shifter 421 may also be identically applied to the second shifter to eighth shifter of the shift circuit 400. Referring to FIG. 17, the first shifter 421 may include a shift data generation circuit 430 and a shift array circuit 440.

The shift data generation circuit 430 may receive the maximum exponent data EX_MAX<7:0> form the comparison circuit (410 in FIG. 15). Furthermore, the shift data generation circuit 430 may receive the first exponent data EX1<7:0> from the first multiplier (MUL1 in FIG. 13) of the multiplication circuit (300 in FIG. 13). The shift data generation circuit 430 may generate and output shift data SFT<7:0> corresponding to differences between values of the maximum exponent data EX_MAX<7:0> and values of the first exponent data EX1<7:0>. The shift data generation circuit 430 may sequentially output the first bit SFT<0> to eighth bit SFT<7> of the shift data SFT<7:0> in a 1 bit unit. The shift data generation circuit 430 may include a subtractor 431 that performs an operation of subtracting the first exponent data EX1<7:0> from the maximum exponent data EX_MAX<7:0>. Bits of the shift data SFT<7:0> may be sequentially transmitted to the shift array circuit 440 in a 1 bit unit in order from a lower bit to an upper bit.

The shift array circuit 440 may receive the first sign data SIGN1<0> and the first mantissa data MA1<15:0> from the first multiplier (MUL1 in FIG. 13) of the multiplication circuit (300 in FIG. 13). The shift array circuit 440 may output the first shifted mantissa data MA_SFT1<23:0> by shifting the first mantissa data MA1<15:0> by the number of bits (i.e., a shift bit) corresponding to an absolute value of the shift data SFT<7:0> that are transmitted by the shift data generation circuit 430.

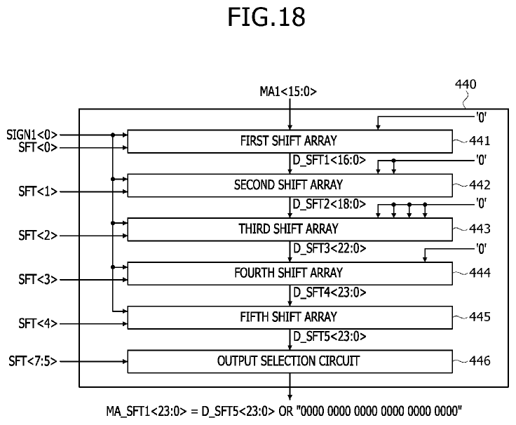

FIG. 18 is a block diagram illustrating the shift array circuit 440 that is included in the first shifter 421 of FIG. 17. Referring to FIG. 18, the shift array circuit 440 may include a first shift array 441 to a fifth shift array 445 and an output selection circuit 446.

The first shift array 441 to the fifth shift array 445 may be constituted identically with the first shift array 110 to fifth shift array 150 that have been described with reference to FIG. 1. Accordingly, the descriptions of the first shift array (110 in FIG. 2) to the fifth shift array (150 in FIG. 6) that have been described with reference to FIGS. 2 to 6 may also be identically applied to the first shift array 441 to fifth shift array 445 that constitute the shift array circuit 440. In this case, the first sign data SIGN1<0> and the first mantissa data MA1<15:0> instead of the sign data SIGN<0> and mantissa data MA<15:0> that are input to the shift array circuit 100 of FIG. 1 may be input to the shift array circuit 440. Furthermore, fifth shifted data D_SFT5<23:0> instead of the shifted mantissa data MA_SFT<23:0> that are output by the fifth shift array 150 of FIG. 1 are output by the fifth shift array 445. If the number of bits of the first mantissa data MA1<15:0>, that is, input data, and the number of bits of the first shifted mantissa data MA_SFT1<23:0>, that is, output data, have values different from values in this example, the descriptions of the “J”-th shift array and “K”-th shift array that have been described with reference to FIGS. 7 to 9 may also be identically applied to the shift arrays that constitute the shift array circuit 440.

The first shift array 441 may output first shifted data D_SFT1<16:0> by performing a first shift operation on the first mantissa data MA1<15:0> at a time point at which the first bit SFT<0> of the shift data SFT<7:0> is transmitted by the shift data generation circuit (430 in FIG. 17). The second shift array 442 may output second shifted data D_SFT2<18:0> by performing a second shift operation on the first shifted data D_SFT1<16:0>, at a late time point, among a time point at which the second bit SFT<1> of the shift data SFT<7:0> is transmitted and a time point at which the first shifted data D_SFT1<16:0> is transmitted. The third shift array 443 may output third shifted data D_SFT3<22:0> by performing a third shift operation on the second shifted data D_SFT2<18:0>, at a late time point among a time point at which the third bit SFT<2> of the shift data SFT<7:0> is transmitted and a time point at which the second shifted data D_SFT2<18:0> is transmitted.

The fourth shift array 444 may output fourth shifted data D_SFT4<23:0> by performing a fourth shift operation on the third shifted data D_SFT3<22:0>, at a late time point, among a time point at which the fourth bit SFT<3> of the shift data SFT<7:0> is transmitted and a time point at which the third shifted data D_SFT3<22:0> is transmitted. The fifth shift array 445 may output fifth shifted data D_SFT5<23:0> by performing a fifth shift operation on the fourth shifted data D_SFT4<23:0>, at a late time point, among a time point at which the fifth bit SFT<4> of the shift data SFT<7:0> is transmitted and a time point at which the fourth shifted data D_SFT4<23:0> is transmitted.

The output selection circuit 446 may receive the fifth shifted data D_SFT5<23:0> from the fifth shift array 445, and may receive the sixth bit SFT<5> to eighth bit SFT<7> of the shift data SFT<7:0> from the shift data generation circuit (430 in FIG. 17). When all of the sixth bit SFT<5> to eighth bit SFT<7> of the shift data SFT<7:0> are “0”, the output selection circuit 446 may output, as the first shifted mantissa data MA_SFT1<23:0>, the fifth shifted data D_SFT5<23:0> that have been received from the fifth shift array 445. In contrast, when at least any one of the sixth bit SFT<5> to eighth bit SFT<7> of the shift data SFT<7:0> is “1”, the output selection circuit 446 may output, as the first shifted mantissa data MA_SFT1<23:0>, data all the bit values of which are “0”, that is, “0000 0000 0000 0000 0000 0000”.

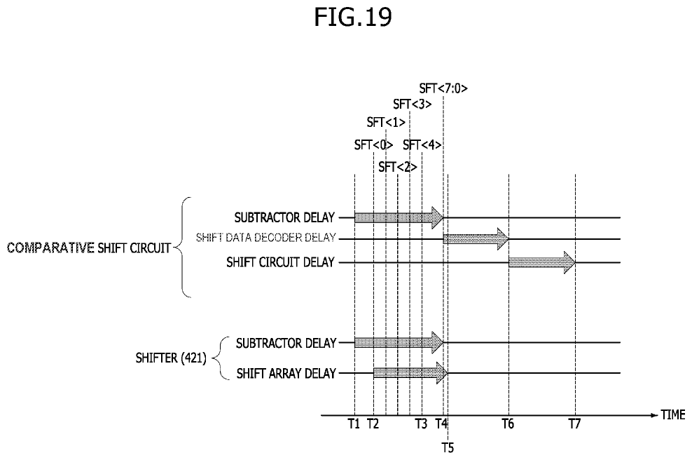

FIG. 19 is a diagram illustrating a comparison between a shift operation speed of the shifter 421 in FIG. 17 and a shift operation speed of a comparative example of a shift circuit.

Referring to FIG. 19, in the case of the comparative shift circuit, a subtractor may generate shift data SFT from a first time point T1 to a fourth time point T4. The decoding of shift data for providing selection data to multiplexers is started at the fourth time point T4 at which all the bits of the shift data SFT<7:0> have been output by the subtractor. When the decoding of the shift data is terminated and the selection data is generated at a sixth time point T6, the shift circuit starts to perform a shift operation and completes all the shift operations at a seventh time point T7.

In contrast, in the case of the shifter 421 in FIG. 17, at the first time point T1, the subtractor (431 in FIG. 17) that is included in the shift data generation circuit (430 in FIG. 17) starts an arithmetic operation for generating the shift data SFT<7:0>. The subtractor 431 may first output the first bit SFT<0> of the shift data SFT<7:0> at the second time point T2. When the subtractor 431 outputs the first bit SFT<0> of the shift data SFT<7:0>, a first shift array 442A of the shift array circuit (440 in FIG. 17) may perform a shift operation. Next, the subtractor 431 may sequentially output the second bit SFT<1>, third bit SFT<2>, fourth bit SFT<3>, and fifth bit SFT<4> of the shift data SFT<7:0> up to the third time point T3. A second shift array 442B to fifth shift array 442E of the shift array circuit (440 in FIG. 17) may sequentially perform shift operations every time points at which the subtractor 431 outputs the second bit SFT<1>, third bit SFT<2>, fourth bit SFT<3>, and fifth bit SFT<4> of the shift data SFT<7:0>. Through such a process, all the shift operations in the shifter 421 of FIG. 17 are completed at the fifth time point T5.

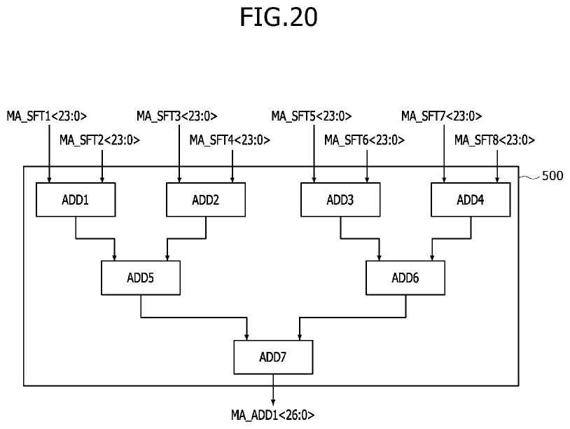

FIG. 20 is a block diagram illustrating an example of the addition circuit 500 that is included in the arithmetic circuit 200 of FIG. 12.

Referring to FIG. 20, the addition circuit 500 may include a first adder ADD1 to a seventh adder ADD7. Each of the first adder ADD1 to the seventh adder ADD7 may have two input terminals and one output terminal. The first adder ADD1 to seventh adder ADD7 may be arranged as a hierarchical structure, such as a tree structure. The first adder ADD1 to the fourth adder ADD4 may be disposed in a first stage, that is, the highest of the addition circuit 500. The fifth adder ADD5 and the sixth adder ADD6 may be disposed in a second stage below the first stage. The seventh adder ADD7 may be disposed in a third stage, that is, the lowest of the addition circuit 500.

The first adder ADD1 of the first stage may receive the first shifted mantissa data MA_SFT1<23:0> from the first shifter (421 in FIG. 15) that constitutes the shift circuit (400 in FIG. 1). Furthermore, the first adder ADD1 may receive the second shifted mantissa data MA_SFT2<23:0> from the second shifter. The first adder ADD1 may add the first shifted mantissa data MA_SFT1<23:0> and the second shifted mantissa data MA_SFT2<23:0>, and may output data that is generated as the results of the addition. Similarly, the second adder ADD2 of the first stage may output addition result data for the third shifted mantissa data MA_SFT3<23:0> and the fourth shifted mantissa data MA_SFT4<23:0>. Similarly, the third adder ADD3 of the first stage may output addition result data for the fifth shifted mantissa data MA_SFT5<23:0> and the sixth shifted mantissa data MA_SFT6<23:0>. Similarly, the fourth adder ADD4 of the first stage may output addition result data for the seventh shifted mantissa data MA_SFT7<23:0> and the eighth shifted mantissa data MA_SFT8<23:0>. The data that is output by each of the first adder ADD1 to the fourth adder ADD4 may have a 25-bit size because a carry bit is added to the data.

The fifth adder ADD5 of the second stage may add the data that is output by the first adder ADD1 and data that is output by the second adder ADD2, and may output addition result data. The sixth adder ADD6 of the second stage may add the data that is output by the third adder ADD3 and the data that is output by the fourth adder ADD4, and may output addition result data. The data that is output by each of the fifth adder ADD5 and the sixth adder ADD6 may have a 26-bit size because a carry bit is added to the data. The seventh adder ADD7 of the third stage may add the data that is output by the fifth adder ADD5 and the data that is output by the sixth adder ADD6, and may output, as first addition mantissa data MA_ADD1<26:0>, data that is generated as the results of the addition. The first addition mantissa data MA_ADD1<26:0> that are output by the seventh adder ADD7 may have a 27-bit size because a carry bit is added to the first addition mantissa data.

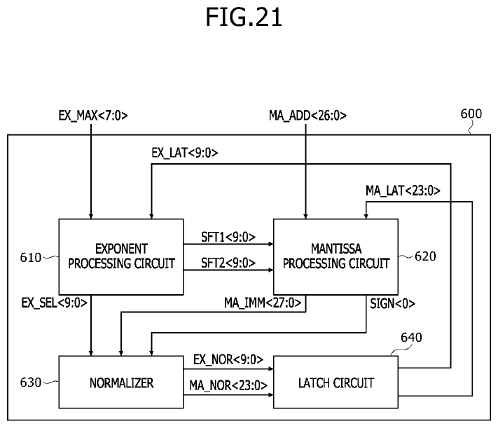

FIG. 21 is a block diagram illustrating an example of the accumulator 600 that is included in the arithmetic circuit 200 of FIG. 12. Referring to FIG. 21, the accumulator 600 may include an exponent processing circuit 610, a mantissa processing circuit 620, a normalizer 630, and a latch circuit 640.

The exponent processing circuit 610 may receive the maximum exponent data EX_MAX<7:0> that are output by the comparison circuit (410 in FIG. 15) of the shift circuit (400 in FIG. 15). The exponent processing circuit 610 may receive latch exponent data EX_LAT<9:0> that are fed back by the latch circuit 640. In this example, the latch exponent data EX_LAT<9:0> may have a 10-bit size, but this is merely one example. The number of bits of the latch exponent data EX_LAT<9:0> may be variously set. The exponent processing circuit 610 may generate subtraction data by performing an operation of subtracting the latch exponent data EX_LAT<9:0> from the maximum exponent data EX_MAX<7:0>. When the MSB of the subtraction data is “0” indicative of a positive number, this may correspond to a case in which the maximum exponent data EX_MAX<7:0> are greater than the latch exponent data EX_LAT<9:0>. In this case, the exponent processing circuit 610 may output the maximum exponent data EX_MAX<7:0> as selected exponent data EX_SEL<9:0>. Furthermore, the exponent processing circuit 610 may output “0” as the first shift data SFT1<9:0>, and may output the subtraction data as the second shift data SFT2<9:0>. When the MSB of the subtraction data is “1” indicative of a negative number, this may correspond to a case in which the maximum exponent data EX_MAX<7:0> are smaller than the latch exponent data EX_LAT<9:0>. In this case, the exponent processing circuit 610 may output the latch exponent data EX_LAT<9:0> as the selected exponent data EX_SEL<9:0>. Furthermore, the exponent processing circuit 610 may output a two's complement of the subtraction data as the first shift data SFT1<9:0>, and may output “0” as the second shift data SFT2<9:0>. The exponent processing circuit 610 may transmit the first shift data SFT1<9:0> and the second shift data SFT2<9:0> to the mantissa processing circuit 620. The exponent processing circuit 610 may transmit the selected exponent data EX_SEL<9:0> to the normalizer 630.

The mantissa processing circuit 620 may receive the addition mantissa data MA_ADD1<26:0> that are output by the addition circuit (500 in FIG. 19). The mantissa processing circuit 620 may receive latch mantissa data MA_LAT<23:0> that are fed back by the latch circuit 640. The mantissa processing circuit 620 may generate shifted addition mantissa data by shifting addition mantissa data MA_ADD<26:0> to the right by a first shift bit corresponding to a value of the first shift data SFT1<9:0> that are transmitted by the exponent processing circuit 610. The mantissa processing circuit 620 may generate shifted latch mantissa data by shifting the latch mantissa data MA_LAT<23:0> to the right by a second shift bit corresponding to a value of the second shift data SFT2<9:0> that are transmitted by the exponent processing circuit 610. The mantissa processing circuit 620 may add the shifted addition mantissa data and the shifted latch mantissa data, and may output, as intermediate mantissa data MA_IMM<27:0>, data that are generated as the results of the addition operation. The mantissa processing circuit 620 may output the MSB of the intermediate mantissa data MA_IMM<27:0> as the sign data SIGN<0>. The mantissa processing circuit 620 may transmit the intermediate mantissa data MA_IMM<27:0> and the sign data SIGN<0> to the normalizer 630.

The normalizer 630 may perform normalization on the selected exponent data EX_SEL<9:0> that are transmitted by the exponent processing circuit 610 and the intermediate mantissa data MA_IMM<27:0> that are transmitted by the mantissa processing circuit 620. Specifically, when the sign data SIGN<0> that is transmitted by the mantissa processing circuit 620 is “0”, the normalizer 630 may search the intermediate mantissa data MA_IMM<27:0> for the highest location of “1”. The normalizer 630 may generate normalized mantissa data MA_NOR<23:0> having a format of “1.xxxx” by shifting the intermediate mantissa data MA_IMM<27:0> based on the retrieved results. When the sign data SIGN<0> that is transmitted by the mantissa processing circuit 620 is “1”, the normalizer 630 may search a two's complement of the intermediate mantissa data MA_IMM<27:0> for the highest location of “1”. The normalizer 630 may generate the normalized mantissa data MA_NOR<23:0> having a format of “1.xxxx” by shifting the two's complement of the intermediate mantissa data MA_IMM<27:0> based on the retrieved results. The normalizer 630 may generate normalized exponent data EX_NOR<9:0> by changing selected exponent data EX_SEL<9:0> by a value corresponding to the number of shifted bits of the intermediate mantissa data MA_IMM<27:0> or the number of shifted bits of the two's complement of the intermediate mantissa data MA_IMM<27:0>. The mantissa processing circuit 620 may transmit the normalized exponent data EX_NOR<9:0> and the normalized mantissa data MA_NOR<23:0> to the latch circuit 640.

The latch circuit 640 may latch the normalized exponent data EX_NOR<9:0> and the normalized mantissa data MA_NOR<23:0> that are transmitted by the normalizer 630. The latch circuit 640 may output the normalized exponent data EX_NOR<9:0> and the normalized mantissa data MA_NOR<23:0> as the latch exponent data EX_LAT<9:0> and the latch mantissa data MA_LAT<23:0>, respectively, at a first logic level of a clock signal, for example, at a high level. The latch circuit 640 may feed the latch exponent data EX_LAT<9:0> back to the exponent processing circuit 610, and may feed the latch mantissa data MA_LAT<23:0> back to the mantissa processing circuit 620.

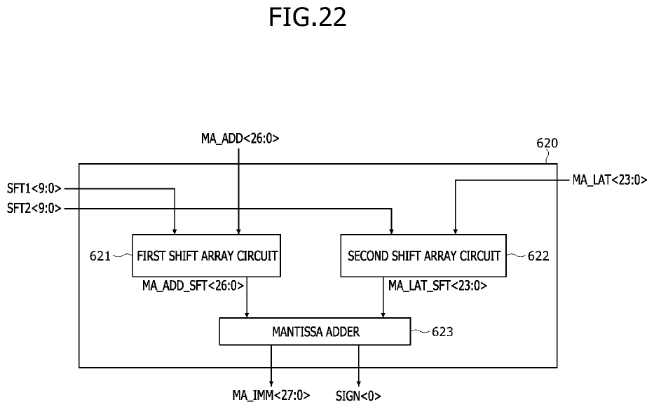

FIG. 22 is a block diagram illustrating an example of the mantissa processing circuit 620 that is included in the accumulator 600 of FIG. 21.

Referring to FIG. 22, the mantissa processing circuit 620 may include a first shift array circuit 621, a second shift array circuit 622, and a mantissa adder 623. The first shift array circuit 621 may receive the addition mantissa data MA_ADD<26:0> that are output by the addition circuit (500 in FIG. 20) and the first shift data SFT1<9:0> that are transmitted by the exponent processing circuit (610 in FIG. 20). The second shift array circuit 622 may receive the latch mantissa data MA_LAT<23:0> that are fed back by the latch circuit (640 in FIG. 20) and the second shift data SFT2<9:0> that are transmitted by the exponent processing circuit (610 in FIG. 20). The first shift array circuit 621 may output shifted addition mantissa data MA_ADD_SFT<26:0> by shifting the addition mantissa data MA_ADD<26:0> to the right by a first shift bit corresponding to a value of the first shift data SFT1<9:0>. The second shift array circuit 622 may output the shifted latch mantissa data MA_LAT_SFT<23:0> by shifting the latch mantissa data MA_LAT<23:0> to the right by a second shift bit corresponding to a value of the second shift data SFT2<9:0>. The mantissa adder 623 may receive the shifted addition mantissa data MA_ADD_SFT<26:0> and the shifted latch mantissa data MA_LAT_SFT<23:0> that are output by the first shift array circuit 621 and the second shift array circuit 622, respectively. The mantissa adder 623 may output the intermediate mantissa data MA_IMM<27:0> by adding the shifted addition mantissa data MA_ADD_SFT<26:0> and the shifted latch mantissa data MA_LAT_SFT<23:0>. The mantissa adder 623 may output the MSB of the intermediate mantissa data MA_IMM<27:0> as the sign data SIGN<0>.

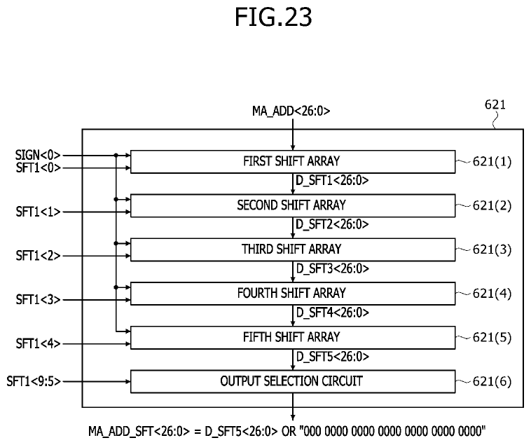

FIG. 23 is a block diagram illustrating the first shift array circuit 621 that is included in the mantissa processing circuit 620 in FIG. 22. The first shift array circuit 621 may receive the 27-bit mantissa data MA_ADD<26:0> of the addition data that is output by the addition circuit (500 in FIG. 12), and may output the 27-bit shifted mantissa data MA_ADD_SFT<26:0> of the addition data. That is, the number of bits of the mantissa data MA_ADD<26:0>, that is, input data, and the number of bits of the shifted mantissa data MA_ADD_SFT<26:0>, that is, output data, are the same.

Referring to FIG. 23, the first shift array circuit 621 may include a first shift array 621(1) to a fifth shift array 621(5), and an output selection circuit 621(6). The first shift array 621(1) to the fifth shift array 621(5) may receive the sign data SIGN<0> of the addition data that is transmitted by the addition circuit (500 in FIG. 12) in common. When the first bit SFT1<0> to fifth bit SFT1<4> of the first shift data SFT1<9:0> are sequentially transmitted to the first shift array 621(1) to fifth shift array 621(5), the first shift array 621(1) to the fifth shift array 621(5) may sequentially perform shift operations.

Specifically, the first shift array 621(1) may perform a first shift operation on the mantissa data MA_ADD<26:0> of the addition data at a time point at which the first bit SFT1<0> of the first shift data SFT1<9:0> is transmitted by the exponent processing circuit (610 in FIG. 21). When the first bit SFT1<0> of the first shift data SFT1<9:0> is “1”, the first shift array 621(1) may output the first shifted data D_SFT1<26:0> by shifting the mantissa data MA_ADD<26:0> of the addition data by a first shift bit (i.e., 1 bit). The second shift array 621(2) may perform a second shift operation on the first shifted data D_SFT1<26:0> at a late time point, among a time point at which the second bit SFT1<1> of the first shift data SFT1<9:0> is transmitted and a time point at which the first shifted data D_SFT1<26:0> are transmitted. When the second bit SFT1<1> of the first shift data SFT1<9:0> is “1”, the second shift array 621(2) may output the second shifted data D_SFT2<26:0> by shifting the first shifted data D_SFT1<26:0> by a second shift bit (i.e., 2 bits).

The third shift array 621(3) may perform a third shift operation on the second shifted data D_SFT6<23:0> at a late time point, among a time point at which the third bit SFT1<2> of the first shift data SFT1<9:0> is transmitted and a time point at which the second shifted data D_SFT2<26:0> are transmitted. When the third bit SFT1<2> of the first shift data SFT1<9:0> is “1”, the third shift array 621(3) may output the third shifted data D_SFT3<26:0> by shifting the second shifted data D_SFT2<26:0> by a third shift bit (i.e., 4 bits). The fourth shift array 621(4) may perform a third shift operation on the third shifted data D_SFT3<26:0> at a late time point, among a time point at which the fourth bit SFT1<3> of the first shift data SFT1<9:0> is transmitted and a time point at which the third shifted data D_SFT3<26:0> are transmitted. When the fourth bit SFT1<3> of the first shift data SFT1<9:0> is “1”, the fourth shift array 621(4) may output the fourth shifted data D_SFT4<26:0> by shifting the third shifted data D_SFT3<26:0> by a fourth shift bit (i.e., 8 bits). The fifth shift array 621(5) may perform a fifth shift operation on the fourth shifted data D_SFT4<26:0> at a late time point, among a time point at which the fifth bit SFT1<4> of the first shift data SFT1<9:0> is transmitted and a time point at which the fourth shifted data D_SFT4<26:0> are transmitted. When the fifth bit SFT1<4> of the first shift data SFT1<9:0> is “1”, the fifth shift array 621(5) may output the fifth shifted data D_SFT5<26:0> by shifting the fourth shifted data D_SFT4<26:0> by a fifth shift bit (i.e., 16 bits).

The output selection circuit 661(6) may receive the fifth shifted data D_SFT5<26:0> from the fifth shift array 661(5), and may receive the sixth bit SFT1<5> to tenth bit SFT1<9> of the first shift data SFT1<9:0> from the exponent processing circuit (610 in FIG. 21). When all of the sixth bit SFT1<5> to eighth bit SFT1<7> of the first shift data SFT1<9:0> are “0”, the output selection circuit 661(6) may output, as the shifted mantissa data MA_ADD_SFT<26:0> of the addition data, the fifth shifted data D_SFT5<26:0> that have been received from the fifth shift array 661(5). In contrast, when at least any one of the sixth bit SFT1<5> to tenth bit SFT1<9> of the first shift data SFT1<9:0> is “1”, the output selection circuit 661(6) may output data all the bit values of which are “0”, that is, “000 0000 0000 0000 0000 0000 0000”, as the shifted mantissa data MA_ADD_SFT<26:0> of the addition data.

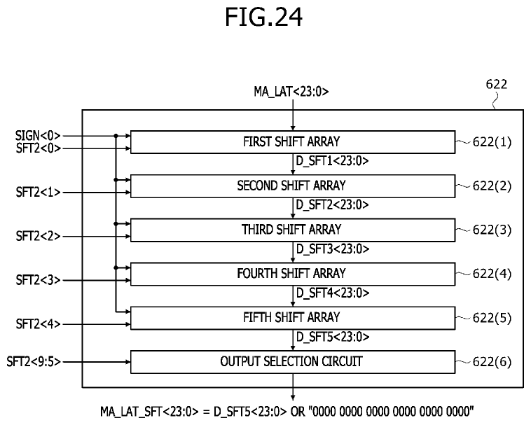

FIG. 24 is a block diagram illustrating the second shift array circuit 622 that is included in the mantissa processing circuit 620 in FIG. 22. The second shift array circuit 622 may receive the 24-bit mantissa data MA_LAT<23:0> of the latch data that are fed back by the latch circuit (640 in FIG. 21), and may output the 24-bit shifted mantissa data MA_LAT_SFT<23:0> of the latch data. That is, the number of bits of the mantissa data MA_LAT<23:0>, that is, input data, and the number of bits of the shifted mantissa data MA_LAT_SFT<23:0>, that is, output data, are the same.

Referring to FIG. 24, the shift array circuit 622 may include a first shift array 622(1) to a fifth shift array 622(5), and an output selection circuit 622(6). The first shift array 622(1) to the fifth shift array 622(5) may receive the sign data SIGN<0> of the latch data that is fed back by the latch circuit (640 in FIG. 21) in common. When the first bit SFT2<0> to fifth bit SFT2<4> of the second shift data SFT<9:0> are sequentially transmitted to the first shift array 622(1) to fifth shift array 622(5), the first shift array 622(1) to the fifth shift array 622(5) may sequentially perform shift operations.

Specifically, the first shift array 622(1) may perform a first shift operation on the mantissa data MA_LAT<23:0> of the latch data at a time point at which the first bit SFT2<0> of the second shift data SFT2<9:0> is transmitted by the exponent processing circuit (610 in FIG. 21). When the first bit SFT2<0> of the second shift data SFT2<9:0> is “1”, the first shift array 622(1) may output the first shifted data D_SFT1<23:0> by shifting the mantissa data MA_LAT<23:0> of the latch data by a first shift bit (i.e., 1 bit). The second shift array 622(2) may perform a second shift operation on the first shifted data D_SFT1<23:0> at a late time point, among a time point at which the second bit SFT2<1> of the second shift data SFT2<9:0> is transmitted and a time point at which the first shifted data D_SFT1<23:0> are transmitted. When the second bit SFT2<1> of the 10 second shift data SFT2<9:0> is “1”, the second shift array 622(2) may output the second shifted data D_SFT2<23:0> by shifting the first shifted data D_SFT1<23:0> by a second shift bit (i.e., 2 bits).

The third shift array 622(3) may perform a third shift operation on the second shifted data D_SFT2<23:0> at a late time point, among a time point at which the third bit SFT2<2> of the second shift data SFT2<9:0> is transmitted and a time point at which the second shifted data D_SFT2<23:0> are transmitted. When the third bit SFT2<2> of the second shift data SFT2<9:0> is “1”, the third shift array 622(3) may output the third shifted data D_SFT3<23:0> by shifting the second shifted data D_SFT2<23:0> by a third shift bit (i.e., 4 bits). The fourth shift array 622(4) may perform a third shift operation on the third shifted data D_SFT3<23:0> at a late time point, among a time point at which the fourth bit SFT2<3> of the second shift data SFT2<9:0> is transmitted and a time point at which the third shifted data D_SFT3<23:0> are transmitted. When the fourth bit SFT2<3> of the second shift data SFT2<9:0> is “1”, the fourth shift array 622(4) may output the fourth shifted data D_SFT4<23:0> by shifting the third shifted data D_SFT3<23:0> by a fourth shift bit (i.e., 8 bits). The fifth shift array 622(5) may perform a fifth shift operation on the fourth shifted data D_SFT4<23:0> at a late time point, among a time point at which the fifth bit SFT2<4> of the second shift data SFT2<9:0> is transmitted and a time point at which the fourth shifted data D_SFT4<23:0> are transmitted. When the fifth bit SFT2<4> of the second shift data SFT2<9:0> is “1”, the fifth shift array 622(5) may output the fifth shifted data D_SFT5<23:0> by shifting the fourth shifted data D_SFT4<23:0> by a fifth shift bit (i.e., 16 bits).

The output selection circuit 662(6) may receive the fifth shifted data D_SFT5<23:0> from the fifth shift array 662(5), and may receive the sixth bit SFT2<5> to tenth bit SFT2<9> of the second shift data SFT2<9:0> from the exponent processing circuit (610 in FIG. 21). When all of the sixth bit SFT2<5> to eighth bit SFT2<7> of the second shift data SFT2<9:0> are “0”, the output selection circuit 662(6) may output, as the shifted mantissa data MA_LAT_SFT<23:0> of the latch data, the fifth shifted data D_SFT5<23:0> that have been received from the fifth shift array 662(5). In contrast, when at least any one of the sixth bit SFT2<5> to tenth bit SFT2<9> of the second shift data SFT2<9:0> is “1”, the output selection circuit 662(6) may output data all the bit values of which are “0”, that is, “0000 0000 0000 0000 0000 0000”, as the shifted mantissa data MA_LAT_SFT<23:0> of the latch data.

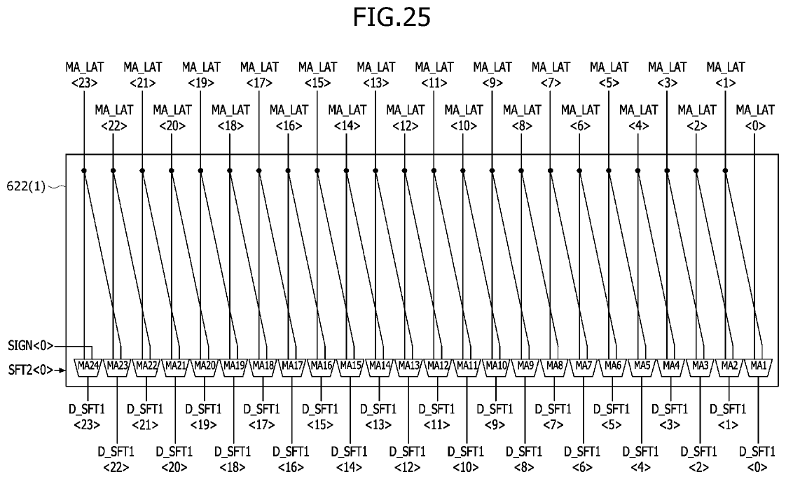

FIGS. 25 to 29 are circuit diagrams illustrating the first shift array 622(1) to fifth shift array 622(5), respectively, which are included in the second shift array circuit 622 in FIG. 24. As described with reference to FIG. 24, the number of bits of the mantissa data MA_LAT<23:0> of the latch data, that is, target data of the second shift array circuit 622, and the number of bits of the shifted mantissa data MA_LAT_SFT<23:0> of the latch data, that is, output data, are the same, that is, 24 bits. Accordingly, the number of bits of the input data and the number of bits of the output data in the first shift array 622(1) to fifth shift array 622(5) that are included in the second shift array circuit 622 are the same, that is, 24 bits. Accordingly, the “K”-th shift array construction that has been described with reference to FIG. 9 may be identically applied to the first shift array 622(1) to fifth shift array 622(5).

First, as illustrated in FIG. 25, the first shift array 622(1) may include 2:1 multiplexers MA1 to MA24 (hereinafter a first group of the first to twenty-fourth multiplexers) having the same number as the number of bits of the first shifted data D_SFT1<23:0>, that is, the output data. The first to twenty-fourth multiplexers MA1 to MA24 of the first group may receive the mantissa data MA_LAT<23:0> of the latch data through first input terminals of the first to twenty-fourth multiplexers MA1 to MA24 for each bit. The first to twenty-third multiplexers MA1 to MA23 of the first group may receive the second to twenty-fourth bits MA_LAT<23:1> of the mantissa data MA_LAT<23:0> of the latch data through second input terminals of the first to twenty-third multiplexers MA1 to MA23. The twenty-fourth multiplexer MA24 of the first group may receive the sign data SIGN<0> through a second input terminal of the twenty-fourth multiplexer MA24.

When the first bit SFT2<0> of the second shift data SFT2<9:0> is “0”, the first to twenty-fourth multiplexers MA1 to MA24 of the first group may output data that are input through the first input terminals. In this case, the first shift array 622(1) may output the mantissa data MA_LAT<23:0> of the latch data as the first shifted data D_SFT1<23:0>. When the first bit SFT2<0> of the second shift data SFT2<9:0> is “1”, the first to twenty-fourth multiplexers MA1 to MA24 of the first group may output data that are input through the second input terminals. In this case, the first shift array 622(1) may output the second to twenty-fourth bits MA_LAT<23:1> of the mantissa data MA_LAT<23:0> of the latch data as the first to twenty-third bits D_SFT1<22:0> of the first shifted data D_SFT1<23:0>, and may output the sign data SIGN<0> as the twenty-fourth bit D_SFT1<23> of the first shifted data D_SFT1<23:0>. As a result, when the first bit SFT2<0> of the second shift data SFT2<9:0> is “1”, the first shift array 622(1) may output the mantissa data MA_LAT<23:0> of the latch data by shifting the mantissa data MA_LAT<23:0> to the right by 1 bit, that is, a first shift bit. In such a process, the first bit MA_LAT<0> of the mantissa data MA_LAT<23:0> of the latch data may be discarded.

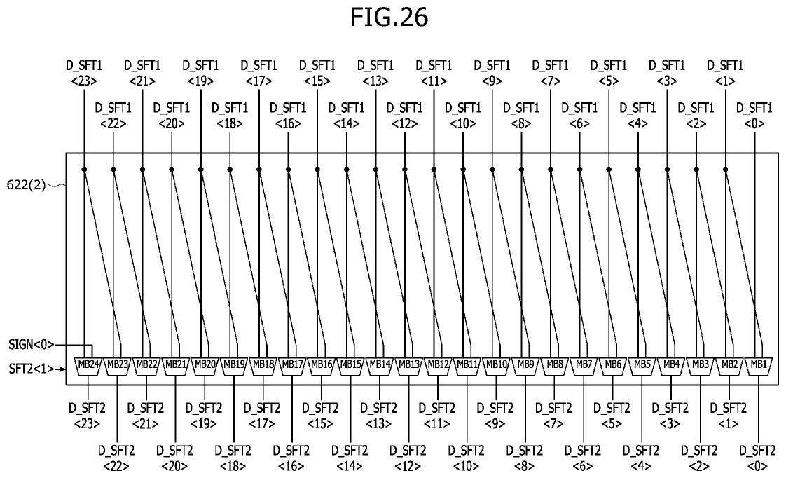

Next, as illustrated in FIG. 26, the second shift array 622(2) may include a second group of first to twenty-fourth multiplexers MB1 to MB24. The first to twenty-fourth multiplexers MB1 to MB24 of the second group may receive the first bit D_SFT1<0> to twenty-fourth bit D_SFT1<23> of the first shifted data D_SFT1<23:0> through first input terminals of the first to twenty-fourth multiplexers MB1 to MB24, respectively. The first to twenty-second multiplexers MB1 to MB22 of the second group may receive the third to twenty-fourth bits D_SFT1<23:2> of the first shifted data D_SFT1<23:0> through second input terminals of the first to twenty-second multiplexers MB1 to MB22. The twenty-third multiplexer MB23 and twenty-fourth multiplexer MB24 of the second group may receive the sign data SIGN<0> of the latch data through second input terminals of the twenty-third multiplexer MB23 and twenty-fourth multiplexer MB24.

When the second bit SFT2<1> of the second shift data SFT2<9:0> is “0”, the first to twenty-fourth multiplexers MB1 to MB24 of the second group may output data that are input through the first input terminals. In this case, the second shift array 622(2) may output the first shifted data D_SFT1<23:0> as the second shifted data D_SFT2<23:0>. When the second bit SFT2<1> of the second shift data SFT2<9:0> is “1”, the first to twenty-fourth multiplexers MB1 to MB24 of the second group may output data that are input through the second input terminals. In this case, the second shift array 622(2) may output the third to twenty-fourth bits D_SFT1<23:2> of the first shifted data D_SFT1<23:0> as the first to twenty-second bits D_SFT2<21:0> of the second shifted data D_SFT2<23:0>, and may output the sign data SIGN<0> as the twenty-third bit D_SFT2<22> and twenty-fourth bit D_SFT2<23> of the second shifted data D_SFT2<23:0>. As a result, when the second bit SFT2<1> of the second shift data SFT2<9:0> is “1”, the second shift array 622(2) may output the first shifted data D_SFT1<23:0> by shifting the first shifted data D_SFT1<23:0> to the right by 2 bits, that is, a second shift bit. In such a process, the first bit D_SFT1<0> and second bit D_SFT1<1> of the first shifted data D_SFT1<23:0> may be discarded.

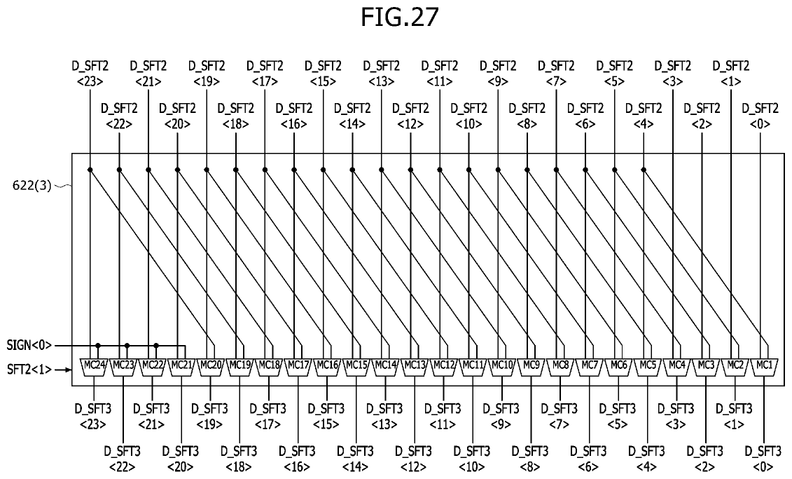

Next, as illustrated in FIG. 27, the third shift array 622(3) may include a third group of first to twenty-fourth multiplexers MC1 to MC24. The first to twenty-fourth multiplexers MC1 to MC24 of the third group may receive the first bit D_SFT2<0> to twenty-fourth bit D_SFT2<23> of the second shifted data D_SFT2<23:0> through first input terminals of the first to twenty-fourth multiplexers MC1 to MC24, respectively. The first to twentieth multiplexers MC1 to MC20 of the third group may receive the fifth bit D_SFT2<4> to twenty-fourth bit D_SFT2<23> of the second shifted data D_SFT2<23:0> through second input terminals of the first to twentieth multiplexers MC1 to MC20, respectively. The twenty-first multiplexer MC21 to twenty-fourth multiplexer MC24 of the third group may receive the sign data SIGN<0> through second input terminals of the twenty-first multiplexer MC21 to twenty-fourth multiplexer MC24.

When the third bit SFT2<2> of the second shift data SFT2<9:0> is “0”, the first to twenty-fourth multiplexers MC1 to MC24 of the third group may output data that are input through the first input terminals. In this case, the third shift array 622(3) may output the second shifted data D_SFT2<23:0> as the third shifted data D_SFT3<23:0>. When the third bit SFT2<2> of the second shift data SFT2<9:0> is “1”, the first to twenty-fourth multiplexers MC1 to MC24 of the third group may output data that are input through the second input terminals. In this case, the third shift array 622(3) may output the fifth to twenty-fourth bits D_SFT3<23:4> of the second shifted data D_SFT2<23:0> as the first to twentieth bits D_SFT3<19:0> of the third shifted data D_SFT3<23:0>, and may output the sign data SIGN<0> as the twenty-first bit D_SFT3<20> to twenty-fourth bit D_SFT3<23> of the third shifted data D_SFT3<23:0>. As a result, when the third bit SFT2<2> of the second shift data SFT2<9:0> is “1”, the third shift array 622(3) may output the second shifted data D_SFT2<23:0> by shifting the second shifted data D_SFT2<23:0> to the right by 4 bits, that is, a third shift bit. In such a process, the first bit D_SFT2<0> to fourth bit D_SFT2<3> of the second shifted data D_SFT2<23:0> may be discarded.

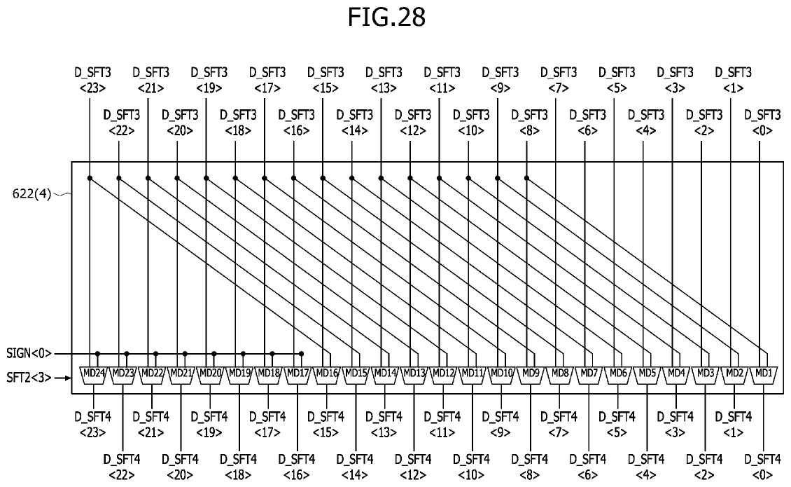

Next, as illustrated in FIG. 28, the fourth shift array 622(4) may include a fourth group of first to twenty-fourth multiplexers MD1 to MD24. The first to twenty-fourth multiplexers MD1 to MD24 of the fourth group may receive the first bit D_SFT3<0> to twenty-fourth bit D_SFT3<23> of the third shifted data D_SFT3<23:0> through first input terminals of the first to twenty-fourth multiplexers MD1 to MD24, respectively. The first to sixteenth multiplexers MD1 to MD16 of the fourth group may receive the ninth bit D_SFT3<8> to twenty-fourth bit D_SFT3<23> of the third shifted data D_SFT3<23:0> through second input terminals of the first to sixteenth multiplexers MD1 to MD16, respectively. The seventeenth multiplexer MD17 to twenty-fourth multiplexer MD24 of the fourth group may receive the sign data SIGN<0> through second input terminals of the seventeenth multiplexer MD17 to twenty-fourth multiplexer MD24.

When the fourth bit SFT2<3> of the second shift data SFT2<9:0> is “0”, the first to twenty-fourth multiplexers MD1 to MD24 of the fourth group may output data that are input through the first input terminals. In this case, the fourth shift array 622(4) may output the third shifted data D_SFT3<23:0> as the fourth shifted data D_SFT4<23:0>. When the fourth bit SFT2<3> of the second shift data SFT2<9:0> is “1”, the first to twenty-fourth multiplexers MD1 to MD24 of the fourth group may output data that are input through the second input terminals. In this case, the fourth shift array 622(4) may output the ninth to twenty-fourth bits D_SFT3<23:8> of the third shifted data D_SFT3<23:0> as the first to sixteenth bits D_SFT4<15:0> of the fourth shifted data D_SFT4<23:0>, and may output the sign data SIGN<0> as the seventeenth bit D_SFT4<16> to twenty-fourth bit D_SFT4<23> of the fourth shifted data D_SFT4<23:0>. As a result, when the fourth bit SFT2<3> of the second shift data SFT2<9:0> is “1”, the fourth shift array 622(4) may output the third shifted data D_SFT3<23:0> by shifting the third shifted data D_SFT3<23:0> to the right by 8 bits, that is, a fourth shift bit. In such a process, the first bit D_SFT3<0> to eighth bit D_SFT3<7> of the third shifted data D_SFT3<23:0> may be discarded.

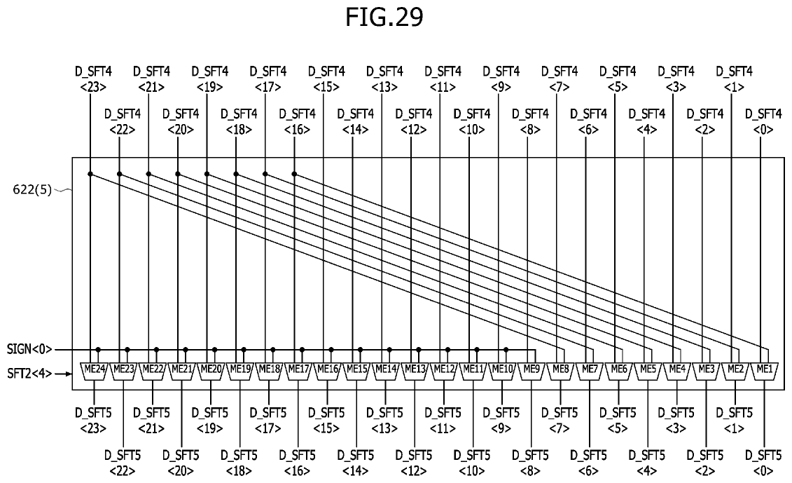

Next, as illustrated in FIG. 29, the fifth shift array 622(5) may include a fifth group of first to twenty-fourth multiplexers ME1 to ME24. The first to twenty-fourth multiplexers ME1 to ME24 of the fifth group may receive the first bit D_SFT4<0> to twenty-fourth bit D_SFT4<23> of the fourth shifted data D_SFT4<23:0> through first input terminals of the first to twenty-fourth multiplexers ME1 to ME24, respectively. The first to eighth multiplexers ME1 to ME8 of the fifth group may receive the seventeenth bit D_SFT4<16> to twenty-fourth bit D_SFT4<23> of the fourth shifted data D_SFT4<23:0> through second input terminals of the first to eighth multiplexers ME1 to ME8, respectively. The ninth multiplexer ME9 to twenty-fourth multiplexer ME24 of the fifth group may receive the sign data SIGN<0> through second input terminals of the ninth multiplexer ME9 to twenty-fourth multiplexer ME24.

When the fifth bit SFT2<4> of the second shift data SFT2<9:0> is “0”, the first to twenty-fourth multiplexers ME1 to ME24 of the fifth group may output data that are input through the first input terminals. In this case, the fifth shift array 622(5) may output the fourth shifted data D_SFT4<23:0> as the fifth shifted data D_SFT5<23:0>. When the fifth 10 bit SFT2<4> of the second shift data SFT2<9:0> is “1”, the first to twenty-fourth multiplexers ME1 to ME24 of the fifth group may output data that are input through the second input terminals. In this case, the fifth shift array 622(5) may output the seventeenth to twenty-fourth bits D_SFT4<23:16> of the fourth shifted data D_SFT4<23:0> as the first bit D_SFT5<0> to eighth bit D_SFT5<7> of the fifth shifted data D_SFT5<23:0>, and may output the sign data SIGN<0> as the ninth bit D_SFT5<8> to twenty-fourth bit D_SFT5<23> of the fifth shifted data D_SFT5<23:0>. As a result, when the fifth bit SFT2<4> of the second shift data SFT2<9:0> is “1”, the fifth shift array 622(5) may output the fourth shifted data D_SFT4<23:0> by shifting the fourth shifted data D_SFT4<23:0> to the right by 16 bits, that is, a fifth shift bit. In such a process, the first bit D_SFT4<0> to sixteenth bit D_SFT4<15> of the fourth shifted data D_SFT4<23:0> may be discarded.

A limited number of possible embodiments for the present teachings have been presented above for illustrative purposes. Those of ordinary skill in the art will appreciate that various modifications, additions, and substitutions are possible. While this patent document contains many specifics, these should not be construed as limitations on the scope of the present teachings or of what may be claimed, but rather as descriptions of features that may be specific to particular embodiments. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A shift array circuit that generates output data having a number of bits greater than a number of bits of target data by shifting the target data by a bit corresponding to a value of shift data,
wherein the shift array circuit comprises a plurality of shift arrays, and
wherein the plurality of shift arrays is configured to receive bits of the shift data for each bit and each configured to perform a shift operation on input data that is input to each of the plurality of shift arrays by a shift bit corresponding to an input bit, among the bits of the shift data.

2. The shift array circuit of claim 1, wherein:
the plurality of shift arrays is disposed in a plurality of stages, respectively, and
the shift array in a lower stage of the plurality of stages is configured to receive output data from the shift array in an upper stage of the plurality of stages and configured to perform the shift operation.

3. The shift array circuit of claim 1, wherein the target data is mantissa data that is included in floating-point data.

4. The shift array circuit of claim 3, wherein the plurality of shift arrays is configured to receive sign data that is included in the floating-point data in common.

5. The shift array circuit of claim 4, wherein at least one of the plurality of shift arrays is configured to receive “0” in common.

6. The shift array circuit of claim 1, wherein:
when the target data is mantissa data of an “N” bit that is included in floating-point data and the output data is shifted mantissa data of an “M” bit, the shift data comprises a number of bits equal to or greater than “K” that corresponds to a smallest number, among natural numbers equal to or greater than “log₂M”,
wherein “N” is a natural number, and
wherein “M” is a natural number greater than “N”.

7. The shift array circuit of claim 6, wherein the plurality of shift arrays comprises:
a first shift array that is disposed in a highest stage of the plurality of stages,
a “J”-th shift array that is disposed between the highest stage and lowest stage of the plurality of stages, and
a “K”-th shift array that is disposed in the lowest stage, and
wherein “J” is a natural number from “2” to “K−1”.

8. The shift array circuit of claim 7, wherein:
the first shift array is configured to perform a first shift operation of receiving sign data that is included in the floating-point data, the mantissa data of the “N” bit, and a least significant bit (LSB) of the shift data and outputting first shifted data of an “N+1” bit,
the “J”-th shift array is configured to perform a “J”-th shift operation of receiving (“J−1”)-th shifted data from the (“J−1”)-th shift array, the sign data, and a “J”-th bit of the shift data and outputting “J”-th shifted data, and
the “K”-th shift array is configured to perform a “K”-th shift operation of receiving (“K−1”)-th shifted data from a (“K−1”)-th shift array, the sign data, and a “K”-th bit of the shift data and outputting shifted mantissa data of the “M” bit.

9. The shift array circuit of claim 8, wherein:
the first shift array is configured to perform the first shift operation at a time point at which the LSB of the shift data is transmitted,
the “J”-th shift array is configured to perform the “J”-th shift operation at a late time point, among a time point at which the “J”-th bit of the shift data is transmitted and a time point at which the (“J−1”)-th shifted data is transmitted, and
the “K”-th shift array is configured to perform the “K”-th shift operation at a late time point, among a time point at which the “K”-th bit of the shift data is transmitted and a time point at which the (“K−1”)-th shifted data is transmitted.

10. The shift array circuit of claim 8, wherein:
the first shift array is configured to shift the mantissa data by a first shift bit when the LSB of the shift data is “1”,
the “J”-th shift array is configured to shift the (“J−1”)-th shift data by a “J”-th shift bit when the “J”-th bit of the shift data is “1”, and
the “K”-th shift array is configured to shift the (“K−1”)-th shift data by a “K”-th shift bit when the “K”-th bit of the shift data is “1”.

11. The shift array circuit of claim 10, wherein:
the first shift bit corresponds to a binary weight of a first bit of the shift data,
the “J”-th shift bit corresponds to a binary weight of the “J”-th bit of the shift data, and
the “K”-th shift bit corresponds to a binary weight of the “K”-th bit of the shift data.

12. The shift array circuit of claim 10, wherein the first shift array comprises a first group of first to (“N+1”)-th multiplexers configured to receive a first bit of the shift data in common through selection terminals of the first to (“N+1”)-th multiplexers.

13. The shift array circuit of claim 12, wherein each of the first to (“N+1”)-th multiplexers of the first group is constituted with a 2:1 multiplexer.

14. The shift array circuit of claim 12, wherein:
the first multiplexer, among the first to (“N+1”)-th multiplexers of the first group, is configured to receive “0” through a first input terminal of the first multiplexer,
the second to (“N+1”)-th multiplexers, among the first to (“N+1”)-th multiplexers of the first group, are configured to receive the mantissa data through first input terminals of the second to (“N+1”)-th multiplexers,
the first to “N”-th multiplexers, among the first to (“N+1”)-th multiplexers of the first group, are configured to receive the mantissa data through second input terminals of the first to “N”-th multiplexers, and
the (“N+1”)-th multiplexer, among the first to (“N+1”)-th multiplexers of the first group, is configured to receive the sign data through a second input terminal of the (“N+1”)-th multiplexer.

15. The shift array circuit of claim 14, wherein the first to (“N+1”)-th multiplexers of the first group are configured to
output, as the first shifted data, data that are input to the first input terminals when the LSB of the shift data is “0”, and
output, as the first shifted data, data that are input to the second input terminals when the LSB of the shift data is “1”.

16. The shift array circuit of claim 10, wherein:
the “J”-th shift array is configured to output “J”-th shifted data of a “Q” bit by receiving the (“J−1”)-th shift data of a “P” bit, and
the “J”-th shift array comprises a “J”-th group of first to “Q”-th multiplexers configured to receive the “J”-th bit of the shift data in common through selection terminals of the first to “Q”-th multiplexers when “P+2^{J-1}” has a value less than the “M”.

17. The shift array circuit of claim 16, wherein each of the first to “Q”-th multiplexers of the “J”-th group is constituted with a 2:1 multiplexer.

18. The shift array circuit of claim 17, wherein:
the first to (“2^{J-1}”)-th multiplexers, among the first to “Q”-th multiplexers of the “J”-th group, are configured to receive “0” through first input terminals of the first to (“2^{J-1}”)-th multiplexers,
the (“2^{J-1}+1”)-th to “Q”-th multiplexers, among the first to “Q”-th multiplexers of the “J”-th group, are configured to receive the (“J−1”)-th shifted data through first input terminals of the (“2^{J-1}+1”)-th to “Q”-th multiplexers,
the first to (“Q−2^{J-1}”)-th multiplexers, among the first to “Q”-th multiplexers of the “J”-th group, are configured to receive the (“J−1”)-th shifted data through second input terminals of the first to (“Q−2^{J-1}”)-th multiplexers, and
the (“Q−2^{J-1}+1”)-th to “Q”-th multiplexers, among the first to “Q”-th multiplexers of the “J”-th group, are configured to receive the sign data through second input terminals of the (“Q−2^{J-1}+1”)-th to “Q”-th multiplexers.

19. The shift array circuit of claim 18, wherein the first to “Q”-th multiplexers of the “J”-th group are configured to output, as the “J”-th shifted data, data that are input to the first input terminals when the “J”-th bit of the shift data is “0”, and output, as the “J”-th shifted data, data that are input to the second input terminals when the “J”-th bit of the shift data is “1”.

20. The shift array circuit of claim 10, wherein:
the “J”-th shift array is configured to output “J”-th shifted data of a “Q” bit by receiving the (“J−1”)-th shifted data of a “P” bit, and
the “J”-th shift array comprises a “J”-th group of first to “M”-th multiplexers configured to receive the “J”-th bit of the shift data in common through selection terminals of the first to “M”-th multiplexers when “P+2^{J-1}” has a value equal to or greater than the “M”.

21. The shift array circuit of claim 20, wherein each of the first to “M”-th multiplexers of the “J”-th group is constituted with a 2:1 multiplexer.

22. The shift array circuit of claim 21, wherein:
the first to (“M−P”)-th multiplexers, among the first to “M”-th multiplexers of the “J”-th group, are configured to receive “0” through first input terminals of the first to (“M−P”)-th multiplexers,
the (“M−P+1”)-th to “M”-th multiplexers, among the first to “M”-th multiplexers of the “J”-th group, are configured to receive the (“J−1”)-th shifted data through first input terminals of the (“M−P+1”)-th to “M”-th multiplexers,
the first to (“M−2^{J-1}”)-th multiplexers, among the first to “M”-th multiplexers of the “J”-th group, are configured to receive (“P−(M−2^{J-1})+1”)-th to “P”-th bits of the (“J−1”)-th shifted data through second input terminals of the first to (“M−2^{J-1}”)-th multiplexers, and
the (“M−2^{J-1}+1”)-th to “M”-th multiplexers, among the first to “M”-th multiplexers of the “J”-th group, are configured to receive the sign data through second input terminals of the (“M−2^{J-1}+1”)-th to “M”-th multiplexers.

23. The shift array circuit of claim 22, wherein the first to “M”-th multiplexers of the “J”-th group are configured to
output, as the “J”-th shifted data, data that are input to the first input terminals when the “J”-th bit of the shift data is “0”, and
output, as the “J”-th shifted data, data that are input to the second input terminals when the “J”-th bit of the shift data is “1”.

24. The shift array circuit of claim 10, wherein the “K”-th shift array comprises a “K”-th group of first to “M”-th multiplexers configured to receive a “K”-th bit of the shift data in common through selection terminals of the first to “M”-th multiplexers.

25. The shift array circuit of claim 24, wherein each of the first to “M”-th multiplexers of the “K”-th group is constituted with a 2:1 multiplexer.

26. The shift array circuit of claim 25, wherein:
the first to “M”-th multiplexers, among the first to “M”-th multiplexers of the “K”-th group, are configured to receive the (“K−1”)-th shifted data through first input terminals of the first to “M”-th multiplexers,
the first to (“M−2^{K-1}”)-th multiplexers, among the first to “M”-th multiplexers of the “K”-th group, are configured to receive (“2^{K-1}1+1”)-th to (“M−1”)-th bits of the (“K−1”)-th shifted data through second input terminals of the first to (“M−2^{K-1}”)-th multiplexers, and
the (“M−2^{K-1}1+1”)-th to “M”-th multiplexers, among the first to “M”-th multiplexers of the “K”-th group, are configured to receive the sign data through second input terminals of the (“M−2^{K-1}1+1”)-th to “M”-th multiplexers.

27. The shift array circuit of claim 26, wherein the first to “M”-th multiplexers of the “K”-th group are configured to
output, as the shifted mantissa data, data that are input to the first input terminals when the “K”-th bit of the shift data is “0”, and
output, as the shifted mantissa data, data that are input to the second input terminals when the “K”-th bit of the shift data is “1”.
